(19) United States
(12) Patent Application Publication
(10) Pub. No.: US 2025/0008740 A1
(43) Pub. Date: Jan. 2, 2025

(54) SELF-ALIGNED MEMORY CELL WITH REPLACEMENT METAL GATE VERTICAL ACCESS TRANSISTOR AND STACKED 3D CAPACITORS

(71) Applicant: Intel Corporation, Santa Clara, CA (US)

(72) Inventors: Wriddhi Chakraborty, Hillsboro, OR (US); Sourav Dutta, Hillsboro, OR (US); Nazila Haratipour, Portland, OR (US); Sou-Chi Chang, Portland, OR (US); Shriram Shivaraman, Hillsboro, OR (US); Gilbert Dewey, Beaverton, OR (US); Uygar Avci, Portland, OR (US)

(73) Assignee: Intel Corporation, Santa Clara, CA (US)

(21) Appl. No.: 18/216,490

(22) Filed: Jun. 29, 2023

(51) Int. Cl. H10B 53/20; H10B 53/30

(52) U.S. Cl. CPC H10B 53/20; H10B 53/30

(57) ABSTRACT

An integrated circuit device includes a stack of capacitors with a vertical first electrode coupled to a stack of individual second electrodes by an insulating storage material between first and second electrodes, and an access transistor coaxially aligned with, and coupled to, the vertical first electrode. The storage material may be a ferroelectric material. A gate dielectric of the access transistor may be around, and coaxial with, a channel region. The channel region may be vertically oriented and coaxial with the first electrode. A second access transistor may be similarly aligned with the first electrode and the stack of capacitors with the capacitor stack between the transistors. A channel of the second transistor may be around, and coaxial with, a gate dielectric. The transistors and capacitor stack may be in arrays of transistors and capacitor stacks. A self-aligned process may be used to form the capacitor and transistor arrays.

### BACKGROUND

Improvements in computing system performance are continually sought, including by increasing the amount of, and speed of access to, cache memory. Traditional random-access memory (RAM), such as six-transistor (6T) static RAM (SRAM) and three-transistor (3T) dynamic RAM (DRAM) cache memories, are constrained by bit cell scaling limitations. These and other architectures are limited by access transistor scaling limitations. Density improvements often introduce added costs, e.g., due to increased lithography requirements.

New structures and methods are needed to improve cache memories and their access, as well as to reduce associated costs.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A and 1B illustrate cross-sectional profile and plan views of an integrated circuit (IC) device having an array of transistors with vertical channel regions under corresponding vertical stacks of capacitors with shared vertical electrodes, in accordance with some embodiments;

FIG. 2 illustrates a cross-sectional profile view of an IC device having arrays of write and read transistors with vertical channel regions under and over corresponding vertical stacks of capacitors with shared vertical electrodes, in accordance with some embodiments;

FIG. 3 is a flow chart of methods for forming an array of capacitors having a shared electrode vertically aligned with a corresponding access transistor, in accordance with some embodiments;

FIGS. 4A, 4B, 4C, 4D, 4E, 4F, 4G, 4H, 4I, 4J, 4K, 4L, 4M, 4N, 4O, and 4P illustrate cross-sectional profile views of a device with a three-dimensional (3D) array of capacitors having shared vertical electrodes and access transistors vertically aligned, at various stages of manufacture, in accordance with some embodiments;

FIG. 5 illustrates a cross-sectional isometric view of a memory device having a 3D array of capacitors with two-dimensional (2D) arrays of shared vertical electrodes and coaxial access transistors having vertical channel regions, in accordance with some embodiments;

FIG. 6 illustrates a diagram of an example data server machine employing an IC device having a 3D array of storage capacitors with vertical transistors for accessing capacitor stacks coaxial with the transistors, in accordance with some embodiments; and

FIG. 7 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected.” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Materials, structures, and techniques are disclosed to improve the cost and performance of integrated circuit (IC) memory devices. Three-dimensional (3D), stacked storage capacitors may be employed to improve memory storage density by reducing bit cell area and increasing bit counts per access transistor with storage capacitors vertically aligned with their access transistors. Storage density may be further increased by using an access transistor with a reduced footprint shared by, or within, the corresponding storage capacitors. With multiple vertically aligned storage capacitors sharing a footprint with an associated access transistor, self-aligning fabrication methods may be utilized, saving expensive lithography operations.

Many random-access memory (RAM) schemes store information in storage capacitors, e.g., with an insulator material between two conductive electrodes, such as parallel plates. For example, information may be stored as a charge differential across a dielectric material between two plates. The presence (or absence) of a stored charge in the storage capacitor may correspond to a logic value of 1 (or 0). Ferroelectric RAM (FeRAM) may store a bit of information as a polarization (positive or negative, or present or absent) in a ferroelectric material in a ferroelectric capacitor. A ferroelectric capacitor may have the advantage of non-volatility relative to a typical capacitor in a dynamic RAM (DRAM) storage application. Non-volatile FeRAM consumes much less power than DRAM, as bits stored as polarization do not require repeated refreshing of storage capacitors the way DRAM does. FeRAM and ferroelectric capacitors may have advantages (e.g., ease of manufacture, increased memory density or reduced die area, reduced cost, etc.) over other non-volatile memories (such as Resistive RAM (ReRAM), magnetoresistive RAM (MRAM), phase-change memory (PCM) (or phase-change RAM (PRAM)), charge-trap memory, etc.), but these and other types of memory may be employed.

A 3D array of storage capacitors, e.g., ferroelectric capacitors, may include stacks of capacitors, with each stack vertically aligned with a corresponding access transistor. The capacitors may be at various levels over an array of transistors at a lowest level. Each stack may include a first, shared electrode extending vertically and a stack of second, individual electrodes, each above and/or below another and coupled to the shared electrode. For example, the individual electrodes may be around the shared electrode, which may extend vertically through the individual electrodes. An insulating, storage material may couple and separate individual electrodes from the shared electrode. A stack of storage capacitors may be accessed by a single select transistor coupled to the shared electrode in the stack. Valuable die area is conserved by vertically aligning a group of capacitors and by orienting the group over its access transistor.

Die area may be further conserved by deploying the access transistor in the same, small footprint as the shared electrode. A transistor may be oriented with a channel extending vertically, e.g., between and connecting a bitline to a shared, vertical electrode of a capacitor stack. A vertically oriented transistor channel conserves die area by packing adjacent capacitor stacks at a smaller pitch, for example, by arranging transistors over bitlines at the lowest interconnect pitch. Adjacent capacitor stacks might be otherwise be separated by two transistors connected end-to-end, e.g., by twice the contact poly pitch (CPP) with the bitline between adjacent capacitor stacks. For a CPP of 1.8 times the bitline (e.g., metal0) pitch, vertically oriented transistor channels and capacitor stacks can have a pitch equal to the bitline pitch, while a conventional layout would space adjacent capacitor stacks nearly four times as far apart (e.g., twice the CPP=2×1.8=3.6). So vertically oriented transistors conserve die area both by occupying a smaller footprint (shared with storage capacitors over the transistor) and by enabling a tighter, denser interconnection scheme.

A vertically oriented transistor under (and sharing a footprint with) a storage capacitor stack allows for deploying a second vertically oriented transistor over the capacitor stack in the same footprint. A capacitor stack between two access transistors enables a gain cell configuration with decoupled read and write bitlines. Separating the read and write bitlines provides an additional degree of freedom for read and write operations, which allows for more efficient read operations (e.g., quicker current sensing on read-only bitlines) and reduced time and power requirements for write operations (e.g., less precharging of write-only bitlines).

A vertically oriented transistor also enables a self-aligned fabrication flow, which reduces manufacturing costs by eliminating lithography operations. Rather than aligning access transistors and multiple storage capacitors with extra lithography operations, access transistors and storage capacitors can advantageously be formed using the same, high-aspect ratio etch. A hole can be formed with a single etch and one or more transistors can be formed over and/or under a vertical electrode shared by the stack of storage capacitors. This single, high-aspect ratio etch enables the self-aligned fabrication flow and establishes the shared, stacked footprint of the transistor and vertical electrode of the capacitor stack.

The inexpensive, dense, and quickly accessed memory may be used as embedded RAM, e.g., on a chip with, and adjacent to, logic devices in a processor, as well as off-chip memory devices. For example, the memory device disclosed may be implemented as an on-die, embedded memory (e.g., on a N node) or on next or other dies (e.g., N−1 or N−2 nodes).

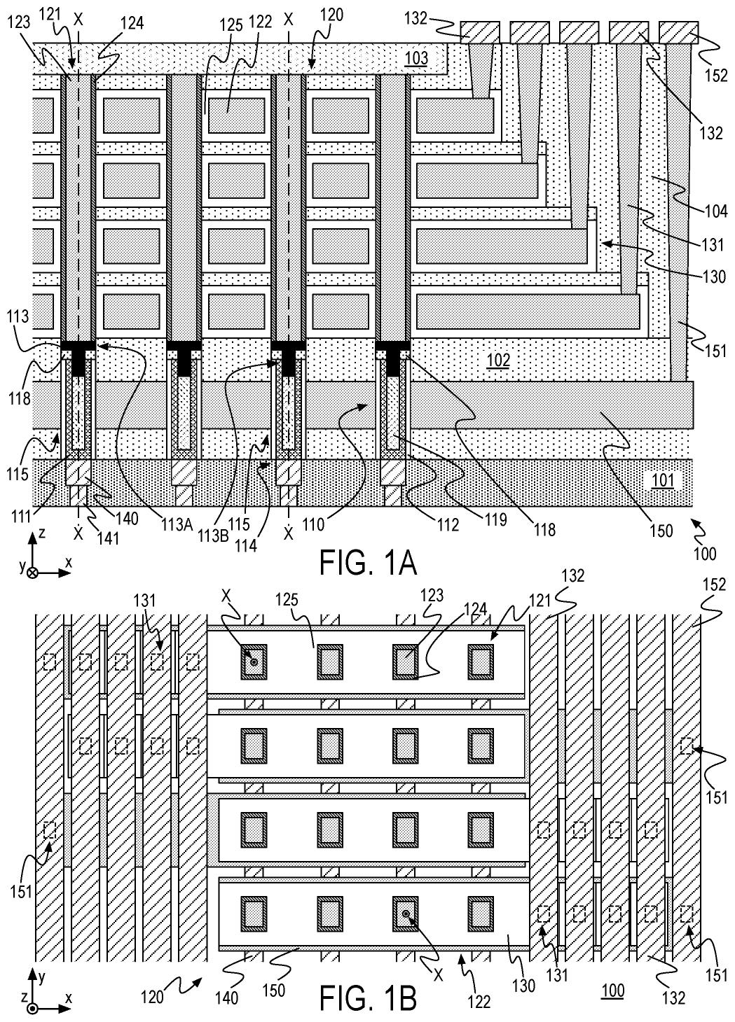

FIGS. 1A and 1B illustrate cross-sectional profile and plan views of an IC device 100 having an array of transistors 110 with vertical channel regions 111 under corresponding vertical stacks of capacitors 120 with shared vertical electrodes 121, in accordance with some embodiments. Capacitors 120 may be used to store information, such as bits of data. Transistors 110 may be access (or select) transistors for accessing (or selecting) capacitors 120 in the associated stack. Each transistor 110 includes a source structure 114 and is coupled at source structure 114 to a bitline 140 and other source structures 114 and transistors 110. Each transistor 110 includes a gate electrode 115 and is coupled at gate electrode 115 to a wordline 150 and other gate electrodes 115 and transistors 110. Each capacitor electrode 122 is coupled to a plateline 130. Each capacitor 120 (and electrode 122) in each stack of capacitors 120 is coupled by a corresponding plateline 130 to other capacitors 120 (e.g., at a same level or z-height) in adjacent stacks of capacitors 120.

FIG. 1A shows a group of transistors 110 in or on a substrate 101, with each transistor 110 under a shared electrode 121 in a stack of capacitors 120. Each stack of capacitors 120 includes a first electrode 121 and multiple second electrodes 122 coupled by an insulator material 125 between electrodes 121, 122. In the embodiment shown in FIG. 1A, each capacitor 120 includes an outer electrode 122 around a portion of vertical electrode 121 and insulator material 125 between electrodes 121, 122. Electrodes 122 need not encircle electrode 121 as in FIG. 1A. Each transistor 110 includes a gate electrode 115, channel region 111 between a drain structure 113 and source structure 114, and a gate dielectric 112 between gate electrode 115 and channel region 111. Each vertical electrode 121 is coupled to drain structure 113 of the corresponding transistor 110. Each vertical electrode 121 is coaxial with the corresponding transistor 110. For a given transistor 110, drain structure 113, source structure 114, gate dielectric 112, and channel region 111 are all coaxial, and each vertical electrode 121 is coaxial with drain structure 113, source structure 114, gate dielectric 112, and channel region 111 of corresponding transistor 110.

Electrode 121, transistor 110, and drain structure 113, source structure 114, gate dielectric 112, and channel region 111 of transistor 110 are coaxial due to sharing a vertical centerline or axis X. Electrode 121 and transistor 110 (and drain structure 113, source structure 114, gate dielectric 112, and channel region 111 of transistor 110) are each centered on respective vertical centerlines on and aligned with axis X. Each of electrode 121, transistor 110, drain structure 113, source structure 114, gate dielectric 112, and channel region 111 are symmetrical (e.g., in the x direction) about shared axis X, which extends vertically (e.g., in the z direction) through each of electrode 121, transistor 110, drain structure 113, source structure 114, gate dielectric 112, and channel region 111. Electrode 121, transistor 110, drain structure 113, and gate dielectric 112 are vertically aligned, e.g., stacked. Herein, the term “vertically aligned” refers to structures being coaxial about a vertical axis and having vertically aligned edges along a lateral dimension (e.g., edges of a higher structure directly over edges of a lower structure below). For example, electrode 121, drain structure 113, and gate dielectric 112 are all vertically aligned, with the same perimeters or footprints stacked one over the other, as determined by the common symmetries about axis X and overlapping edges (e.g., in the x direction) of each of electrode 121, drain structure 113, and gate dielectric 112. First electrode 121 has a vertical centerline, and channel structure or region 111 has vertical centerline aligned with the vertical centerline of first electrode 121. Transistors 110 being vertically aligned with a corresponding stack of capacitors 120 beneficially enables bit cells (e.g., arrays of capacitors 120) to be more tightly packed (saving valuable die area) and allows for self-aligned methods during manufacture (reducing both the number of expensive lithography operations required and the associated costs).

Transistors 110 may be access or select transistors 110 that enable the reading and/or writing of data bits from and/or to storage capacitors 120. Transistors 110 may be of any suitable form and material(s). In the embodiment shown in FIG. 1A, gate dielectric 112 is around (and coaxial with) channel region 111 in a gate-all-around (GAA) transistor 110. Gate dielectric 112 (and the gate structure) surrounds channel structure or region 111. Channel region 111 is around (and coaxial with) plug 119, which may be of an insulator material and provide mechanical support in the interior of transistor 110. Channel region 111 is a channel structure that extends vertically between and couples drain and source structures 113, 114. Channel structure or region 111 is that portion of a semiconductor material between drain and source structures 113, 114 and adjacent gate electrode 115, e.g., between edges of gate electrode 115. Gate dielectric 112, between gate electrode 115 and channel region 111, enables electrostatic control (e.g., by gate electrode 115 and coupled wordline 150) of conduction in and through channel region 111. Conduction of channel region 111 (and, thereby, of transistor 110) electrically connects source structure 114 (and bitline 140 coupled to source structure 114) to drain structure 113 (and electrode 121, which is a common node for all of capacitors 120 in that stack).

Channel region 111 may be of any suitable form and material(s). Advantageously, channel region 111 is of a material that may be deposited conformally in thin layers at low temperatures and low cost. In many embodiments, channel region 111 includes a metal oxide. Channel region 111 may have any morphology or microstructure. In some embodiments, channel region 111 is substantially amorphous (without discernable long-range order) or slightly crystalline. However, depending on the substrate and the deposition process, channel region 111 may be of a more-ordered polycrystalline (e.g., microcrystalline or nanocrystalline) material, such as a metal-oxide material.

Channel region 111 may include a two-dimensional (2D) material, such as an in situ-grown material. Channel region 111 may be deposited to a thickness of less than 1 nm and up to tens of nanometers, for example, 20 nm or more. The semiconductor thickness, e.g., of an oxide semiconductor, can be chosen to optimize selected transistor channel characteristics, for example, high carrier mobility and a material band gap and resistivity that is tunable by a dopant that impacts the charge carrier (e.g., electron) concentrations.

In some embodiments, channel region 111 includes amorphous or polycrystalline materials that include a metal and oxygen, such as a metal oxide. In some embodiments, channel region 111 includes a thin, metal-oxide film that may be semiconducting substantially as-deposited, and/or following some subsequent activation process, such as a thermal anneal. In many embodiments, oxide semiconductor materials primarily include one or more metals (M1, M1M2, M1M2M3, etc.) and oxygen. The metal(s) may be from the transition metals (e.g., IUPAC group 4-10) or post-transition metals (e.g., IUPAC groups 11-15). The metal oxide compounds may be suboxides (A₂O), monoxides (AO), binary oxides (AO₂), ternary oxides (e.g., ABO₃), and mixtures thereof, for example. In some embodiments, channel region 111 includes oxygen and at least one of Mg, Cu, Zn, Sn, Ti, In, Ga, or Al.

Channel region 111 may include any atomic concentration ratio of metal constituents. For example, a binary metal alloy M1_{y}M2_{1-y} may include any atomic percent of a first metal (M1) and a complementary atomic percent of a second metal (M2) or metalloid/non-metal. A ternary alloy M1_{y}M2_{z}M3_{1-y-z} may include any atomic percent of metal M1, any atomic percent of metal M2, and a complementary atomic percent of a third metal (M3), such that y and z are both greater than 0, but sum to less than 1. In some embodiments, channel region 111 includes a zinc oxide (ZnOₓ), such as Zn(II) oxide, or ZnO, zinc peroxide (e.g., ZnO₂) or a mixture of ZnO and ZnO₂. In some specific embodiments, channel region 111 includes zinc oxide and indium oxide (e.g., In₂O₃). In some further embodiments, channel region 111 includes a composition of indium, gallium, zinc, and oxygen (IGZO), e.g., zinc oxide, indium oxide, and gallium oxide (e.g., Ga₂O₃). The metal atomic composition ratio, for example, Ga to each of In and Z (Ga:In:Z), may vary. In some examples, channel region 111 includes a Ga-rich IGZO.

Channel region 111 may include one or more dopants, such as a metal or a nonmetallic dopant, such as N, O, H, F, Cl, Si, or Ge, that may introduce electron vacancies or oxygen vacancies. Whether metallic or non-metallic, most dopants can be readily detected along with the metal majority constituents by one or more chemical analysis techniques, such as X-ray photoelectron spectroscopy, energy dispersive spectroscopy, or electron energy loss spectroscopy.

Gate dielectric 112 provides electrical insulation between channel region 111 and gate electrode 115 (e.g., wordline 150). Gate dielectric 112 may have more than one layer. Gate dielectric 112 may be of any suitable material(s). The one or more layers of gate dielectric 112 may include a silicon oxide, silicon dioxide (SiO₂), a silicon oxynitride, etc. Advantageously, gate dielectric 112 includes a high-permittivity (“high-K”) dielectric, which may improve transconductance. For example, a high-K (or high-dielectric constant) dielectric 112 may result in increased conductance of transistor 110 (through channel region 111) for a given signal at gate electrode 115 (for example, on wordline 150) or a lower required gate signal for a same conductance. A high-K gate dielectric 112 may enable a thicker layer of dielectric 112 for a same desired transconductance, which may provide better isolation.

In many embodiments, gate dielectric 112 is an oxide or other layer grown or deposited before forming a channel material over the dielectric material. A high-K dielectric material may include one or more of various elements, such as hafnium, silicon, oxygen, titanium, tantalum, lanthanum, aluminum, zirconium, barium, strontium, yttrium, lead, scandium, niobium, and zinc. For example, the dielectric material may include a combination of metal oxides and/or one or more oxides with an added dopant, e.g., to increase a permittivity of the dielectric material. Examples of high-K materials that may be used in gate dielectric 112 include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, etc. In some embodiments, an annealing process may be carried out on the gate dielectric 112 to improve its quality when a high-K material is used.

Source structure 114 may be below channel region 111 and between channel region 111 and bitline 140. Source structure 114 is symmetrical about vertical axis X and is coaxial with vertical electrode 121 and transistor 110, including channel region 111, gate dielectric 112, and drain structure 113. Source structure 114 may include semiconductor material below channel region 111 and gate electrode 115 (e.g., above wordline 150). Source structure 114 may include a contact, such as a metal contact over bitline 140 and under the semiconducting material of transistor 110. In some embodiments, an interface is present between source structure 114 and bitline 140. In some embodiments, no distinct metal contact is between bitline 140 and a semiconducting material of source structure 114.

Drain structure 113 may be above channel region 111 and between channel region 111 and vertical electrode 121. Drain structure 113 is symmetrical about vertical axis X and is coaxial with vertical electrode 121 and transistor 110, including channel region 111, gate dielectric 112, and source structure 114. Drain structure 113 may include semiconductor material above channel region 111 and gate electrode 115 (e.g., above wordline 150). Drain structure 113 may include a contact, such as a metal contact over the semiconducting material of transistor 110. In some embodiments, an interface is present between drain structure 113 and electrode 121. In some embodiments, no distinct metal contact is between electrode 121 and a semiconducting material of drain structure 113.

In some embodiments, as in the exemplary embodiment shown, drain structure 113 includes coaxial upper and lower portions 113A. 113B, e.g., to increase contact. Upper portion 113A shares has a footprint and perimeter vertically aligned with a footprint and perimeter of, e.g., first electrode 121, which may maximize contact between drain structure 113 and first electrode 121. Lower portion 113B is narrower and extends into, and increases contact with, the semiconductor material of transistor 110. Drain structure 113 may be isolated from gate dielectric 112 by an isolation 118, e.g., around lower portion 113B and coaxial with and under upper portion 113A.

As shown, select or access transistors 110 couple (and electrically connect (or not)) bitlines 140 to corresponding first electrodes 121 and capacitors 120. Each transistor 110 has a source structure 114 and drain structure 113. Each transistor 110 and source structure 114 shown in FIG. 1A is coupled to a corresponding bitline 140. Each transistor 110 and drain structure 113 shown in FIG. 1A is coupled to a corresponding first electrode 121. Conduction of channel region 111 and of transistor 110 electrically connects bitline 140 (coupled to source structure 114) to electrode 121 (coupled to drain structure 113) and all of capacitors 120 in that stack. The conduction of access transistor 110 is controlled by the voltage signal applied to gate electrode 115, e.g., by wordline 150. Since first electrode 121 is a shared node for all capacitors 120 in the stack, any bit stored in any of the group's capacitors 120 is accessible by the single access transistor 110.

With transistor 110 accessing the entire memory array of storage capacitors 120 via shared electrode 121, individual control of capacitors 120 is by controlling second electrodes 122 using platelines 130 (in concert with access transistor 110 using, e.g., wordline 150). With transistor 110 conducting, an individual bit corresponding to one of capacitors 120 can be read (or written) by applying a voltage differential across that capacitor 120 (and only that capacitor 120) by applying the same voltage level on drain structure 113 and all platelines 130 but for plateline 130 connected to second electrode 122 corresponding to capacitor 120 to be read (or written). In this way, a voltage can be applied across shared electrode 121 and an individual second electrode 122 to charge (or write to) or discharge (or read from) only that capacitor 120. Control of storage capacitors 120 may vary with the type of capacitor 120, e.g., depending on the characteristics of insulator material 125.

The 3D array of capacitors 120 is arranged in an array of stacks of capacitors 120. Each stack of capacitors 120 includes a vertical first electrode 121 and a group of stacked second electrodes 122 coupled to electrode 121 by insulator material 125. Each capacitor 120 includes one of second electrodes 122, a specific (or individual or divided) portion of first electrode 121, and material 125 between electrodes 121, 122. While electrode 121 is common or shared by the corresponding stack of capacitors 120, each capacitor 120 includes the specific, individual portion of first electrode 121 coupled by material 125 to the specific electrode 122 of that capacitor 120. (A second electrode 122 in one stack may be coupled to one or more second electrodes 122 in one or more adjacent stacks, and the coupled second electrodes 122 may be portions of a substantially continuous conductive element, e.g. a metal line, such as plateline 130. In such embodiments, a second electrode 122 may be considered to be the conductive material, e.g., a metal, immediately adjacent to insulator material 125 or nearest to first electrode 121.)

Within a stack of capacitors 120, a group of stacked second electrodes 122 are vertically aligned, all coaxial and sharing a same footprint or lateral area. In the embodiment of FIG. 1A, within a stack of four capacitors 120, all four second electrodes 122 are all coaxial with first electrode 121. The height of a stack of capacitors 120 may be shorter or taller, and the quantity of capacitors 120 in any stack may be less or greater. The quantity of capacitors 120 in any stack may be chosen to be a convenient factor of a word length, e.g., to be four bits, eight bits, etc. As shown in FIG. 1A, four second electrodes 122 are around first electrode 121, and first electrode 121 extends vertically through four second electrodes 122. In some embodiments, vertically aligned second electrodes 122 are coupled to, but not coaxial with, first electrode 121. For example, vertically aligned second electrodes 122 may run alongside a vertical first electrode 121 with insulator material 125 between a sidewall of first electrode 121 and sidewalls of second electrodes 122.

A transistor 110 is under first electrode 121 of each stack of capacitors 120, and first electrode 121 is coupled to, and coaxial with, transistor 110 and the corresponding drain structure 113. First electrodes 121 are vertically aligned with, and coupled to, corresponding channel regions 111 in the array of transistors 110. Each first electrode 121 is coupled to channel region 111 by drain structure 113 between electrode 121 and channel region 111. First electrodes 121 and channel regions 111 are vertically aligned because each first electrode 121 is coaxial, and has a shared, stacked footprint (or perimeter or outline), with the coupled channel region 111. First electrodes 121 are vertical, conductive structures, e.g., metal vias, symmetrical about axis X. As with some vias, electrodes 121 may have a slight, vertical taper, for example, with a slightly wider cross-section (and a slightly longer lateral dimension) at a top of electrode 121 and a slightly narrower cross-section (and a slightly shorter lateral dimension) at a bottom of electrode 121. In some embodiments, first electrodes 121 and channel regions 111 are substantially vertically aligned with each first electrode 121 coaxial with the coupled channel region 111 and with first electrodes 121 and channel regions 111 having footprints centered on axis X where one footprint has a slightly shorter lateral dimension and the other footprint has a slightly longer lateral dimension. Likewise, any second electrode 122 around a first electrode 121 with a slight vertical taper may be characterized as substantially vertically aligned with the other second electrodes 122 around that first electrode 121 (e.g., all coaxial and having overlapping footprints centered on axis X with slightly shorter and longer lateral dimensions).

Electrodes 121, 122 may be of any suitable form and material(s). In many embodiments, electrodes 121, 122 include one or more of the same conductive materials. In many embodiments, electrodes 121, 122 include one or more metals. In some embodiments, one or both of electrodes 121, 122 include liner and fill or bulk metals. For example, electrodes 121 may include a liner material 124 around a fill material 123. In some embodiments, no discernable liner material 124 is present around fill material 123. Electrodes 121, 122 may be of any suitably conductive material(s), such as tungsten, titanium, nitrogen (e.g., in a titanium nitride or nitride of another metal), ruthenium, molybdenum, cobalt, copper, etc.

As described elsewhere herein, capacitors 120 may be ferroelectric capacitors 120 or other storage capacitors 120. Although ferroelectric materials may primarily be described here and may have advantages over other materials, these and other types of memory may be employed.

In the examples shown in FIG. 1A and elsewhere herein, material 125 may advantageously include a ferroelectric material with a higher relative permittivity than high-K dielectric materials that lack the spontaneous polarization of materials in a ferroelectric phase (e.g., orthorhombic, non-centrosymmetric crystallinity). For example, a high k dielectric comprising predominantly hafnium and oxygen (HfOₓ), but not in a ferroelectric phase, may have a relative permittivity in the range of 10-14. However, hafnium oxide in a ferroelectric phase may have a relative permittivity exceeding 25 (e.g., 30). Although in both instances the HfOₓ comprises predominantly hafnium and oxygen, material 125 advantageously includes a ferroelectric phase of a material, e.g., hafnium oxide. In the case of hafnium oxide, such phases may be achieved, for example, through the addition of a dopant, such as niobium, titanium, silicon, germanium, aluminum, yttrium, zirconium, lanthanum, scandium, etc.

Many ferroelectric materials are suitable for use in material 125. As used herein, the term ferroelectric material indicates a material that has a spontaneous electric polarization that may be controlled by the application of an external electric field. Ferroelectric materials exhibit a hysteresis such that when a positive voltage is applied, a positive residual charge is maintained even as the voltage falls to zero. This residual charge is characterized as polarization. To remove the polarization, a negative voltage must be applied. Furthermore, the negative voltage may be used to provide a negative polarization, which is also maintained as the voltage again goes to zero. In capacitors 120 and other capacitor structures discussed herein, a differential voltage must be applied across a ferroelectric capacitor 120 to polarize material 125 (i.e., the ferroelectric material) either positively or negatively. This positive or negative polarity may then be read as 1 or 0. Besides the advantage of higher relative permittivity, ferroelectric materials and this polarization have this non-volatility advantage over non-ferroelectric dielectric materials.

Any suitable ferroelectric material may be used. In some embodiments, material 125 has a perovskite structure. Perovskite materials have the general formula ABX₃ and may be in a structure deviated from a cubic structure. While both A and B are positively charged ions, they may be of different sizes with the A atoms generally larger than the B atoms. The X is a negatively charged ion (frequently an oxide) that bonds to both A and B cations. These perovskite structures can include compounds where the A and/or B sites include multiple materials (e.g., A1ₓ₋₁A2ₓ and/or B1_{y-1}B2_{y}). The X site may deviate from, e.g., a cubic coordination configuration as ions within the A and B sites undergo changes in their oxidation states. In some embodiments, material 125 includes lead, zirconium, titanium, and oxygen (e.g., lead zirconium titanate, Pb[ZrₓTi₁₋ₓ]O₃, (PZT)). In some embodiments, material 125 includes barium, titanium, and oxygen (e.g., barium titanate, BaTiO₃). In some embodiments, material 125 includes lead, titanium, and oxygen (e.g., lead titanate, PbTiO₃). In some embodiments, material 125 includes barium, strontium, titanium, and oxygen (e.g., barium strontium titanate, BaSrTiO₃). In some embodiments, material 125 include other materials with perovskite structures.

Advantageously, material 125 includes a ferroelectric material that may be deposited conformally and to very narrow thicknesses, such as a 2D material. Such is the case with numerous oxides of hafnium or similar metals. In some embodiments, material 125 includes hafnium, zirconium, and oxygen (HZO) (e.g., hafnium zirconium oxide, Hf₁₋ₓZrₓO₂). In some such embodiments, material 125 includes dopants, e.g., titanium or niobium. In some embodiments, material 125 includes hafnium, titanium, and oxygen (e.g., hafnium titanium oxide, Hf₁₋ₓTiₓO₂). In some embodiments, material 125 includes hafnium, scandium, and oxygen. In some embodiments, material 125 includes zirconium and oxygen (e.g., zirconium dioxide, ZrO₂). In some embodiments, material 125 includes niobium and oxygen. Although, e.g., hafnium zirconium oxide or doped HfOₓ are exemplary embodiments that can be advantageously conformally deposited by atomic layer deposition (ALD), material 125 may also have other compositions similarly amenable to being deposited at temperatures compatible with, e.g., back-end-of-line (BEOL) structures and with similar thickness conformality. The use of 2D ferroelectric materials allows for arrays with smaller capacitors and increased memory density. In some embodiments, capacitors 120 have a ferroelectric material thickness of 10 nm. In some embodiments, capacitors 120 have a ferroelectric material thickness of 2 nm. Non-ferroelectric materials may also be employed in material 125.

In some embodiments, material 125 has a wurtzite crystalline structure. In some embodiments, material 125 includes aluminum, scandium, and nitrogen (e.g., aluminum scandium nitride, AlₓSc₁₋ₓN, which may be aluminum nitride doped with scandium). Aluminum scandium nitride may advantageously be conformally deposited by ALD, as a 2D material, and at low temperatures (e.g., <250° C.), which provides compatibility with BEOL flows. Other ferroelectric materials may be employed.

In the examples of FIGS. 1A, 1B, platelines 130 are integrated with, and/or are coupled to, second electrodes 122 of capacitors 120. Platelines 130 are parallel conductive lines that couple stacks of second electrodes 122 in adjacent stacks of capacitors 120. Platelines 130 extend in a direction, e.g., the x direction, orthogonal to a direction, e.g., the y direction, of bitlines 140 under, or at a lower level of, transistors 110. Platelines 130 extend in a same direction, e.g., the x direction, of wordlines 150 at transistors 110. In some embodiments, lower platelines 130 in a first direction are coupled to upper platelines 132 in an orthogonal second direction, e.g., at a different level.

Bitlines 140 are coupled to transistors 110 at source structures 114, and source structures 114 couple bitline 140 to channel regions 111. Bitlines 140 extend in a direction, e.g., the y direction, orthogonal to a direction, e.g., the x direction, of wordlines 150 at transistors 110. Bitlines 140 may couple (e.g., electrically connect) to structures below by bitline via 141.

In the examples of FIGS. 1A, 1B, wordlines 150 are integrated with gate electrodes 115 of transistors 110. Adjacent gate electrodes 115 may be coupled to one another, and the coupled gate electrodes 115 may be portions of a substantially continuous conductive element, e.g. a metal line, such as wordline 150. In such embodiments, a gate electrode 115 may be considered to be the conductive material, e.g., a metal, immediately adjacent to gate dielectric 112. In such embodiments, a diameter of gate electrode 115 may be considered to be substantially equal to the outer diameter of gate dielectric 112. In some embodiments, lower wordlines 150 in a first direction are coupled to upper wordlines 152 in an orthogonal second direction, e.g., at a different level.

Device 100, including the array of transistors 110 and the array of stacks of capacitors 120, is in or on substrate 101. Substrate 101 may be, for example, an integrated circuit (IC) die or wafer, and may be of any suitable material or materials. The substrate may include a semiconductor or insulator material, including a crystalline material. In some embodiments, the substrate includes monocrystalline silicon (Si), germanium (Ge), silicon germanium (SiGe), a III-V alloy material (e.g., gallium arsenide (GaAs)), a silicon carbide (e.g., SiC), a sapphire (e.g., Al₂O₃), or any combination thereof. Substrate 101 may also include other semiconductor materials, metals, dielectrics, dopants, and other materials commonly found in semiconductor substrates.

Transistors 110 and capacitors 120 may be at a same level as, above, or below other such devices and/or other transistors in or on substrate 101, such as logic devices (e.g., metal-oxide semiconductor (MOS) field-effect transistors (FETs), including complementary MOS (CMOS) devices). For example, device 100 may be within interconnect layers over CMOS devices in a processor of an IC device. Device 100 may be in a front- or backside of substrate 101.

Substrate 101 may include various dielectrics 102, 103, 104, which may be or include insulating materials with a same or different compositions. Dielectrics 102, 103, 104 may be low-permittivity (“low-K”) dielectrics that isolate various conductive elements. For example, dielectric 102 may be an inter-metal dielectric (IMD), and dielectric 103 may be the same (or a different) material. Dielectric 103 may be an inter-layer dielectric (ILD), e.g., an etch-stop layer, hermetic seal, etc. Staircase dielectric 104 may be the same (or a different) material as dielectrics 102, 103.

FIG. 1B illustrates a possible routing scheme of platelines 130, bitlines 140, and wordlines 150 in an overhead plan view of device 100 (e.g., as if dielectric 102, 103, 104 are transparent). Multiple embodiments of the bit cells shown in FIG. 1A (with routing variations) are arranged along the y axis. Additional upper platelines 132 and wordline 152 are shown on an opposite side of device 100 from platelines 132 and wordline 152 of FIG. 1A. The dashed outlines of plateline and wordline vias 131, 151 are shown to indicate which platelines 130 are coupled to which upper platelines 132 and which wordlines 150 are coupled to which upper wordlines 152. In the plan view of FIG. 1B, transistors 110 are obscured by platelines 130, which are above transistors 110. Transistors 110 (not shown) are centered on axes X (some of which are shown) and below (and obscured by) shared electrodes 121 of capacitors 120 (which are both also centered on axes X). An array of capacitor 120 stacks is spaced out over the x and y directions. An array of transistors 110 are spaced out over the x and y directions, each transistor 110 vertically aligned under a corresponding vertical electrode 121. The 2D array of transistors 110 (in the x and y directions) is an array of multiple one-dimensional arrays (e.g., multiple transistors 110 in a row in the x direction, coupled by, and spaced regularly along, a wordline 150) aligned in a second dimension (e.g., multiple wordlines 150 and rows of transistors 110, coupled by bitlines 140 running in the y direction). The third dimension of the 3D array of capacitors 120 is in the z direction (as shown in FIG. 1A) and is provided by the vertical arrangement of capacitors 120 in stacks over the array of transistors 110.

Vias 131, 151 couple various lines (and not other lines) to provide orthogonal control of every storage capacitor 120 of device 100. As described elsewhere herein, capacitors 120 are controlled by coordinating the voltage levels on both electrodes 121, 122 for each capacitor 120 individually. Shared electrode 121 is controlled by transistor 110 and second electrodes 122 are controlled by their corresponding platelines 130. (In the plan view of FIG. 1B, second electrodes 122 are obscured by platelines 130, which are above and below second electrodes 122.) Control of transistor 110 is by wordline 150, and control of individual capacitors 120 is also coordinated with bitlines 140, which are electrically connected to selected capacitors 120. Each capacitor 120 may be accessed with a unique combination of platelines 130, bitlines 140, and wordlines 150, as previously described.

Wordlines 150 (under platelines 130) run in a first direction (the x direction) and are coupled to upper wordlines 152 running in an orthogonal second direction (the y direction) at a different level in the interconnect layer(s). In many embodiments, platelines 130 and wordlines 150 have a same line width. Platelines 130 (over wordlines 150) run in a first direction (the x direction) and are coupled to upper platelines 132 running in an orthogonal second direction (the y direction) at a different level in the interconnect layer(s). Bitlines 140 extend in a direction (the y direction) orthogonal to a direction (the x direction) of lower wordlines 150 at transistors 110. Bitlines 140 extend in a direction parallel to a direction of upper wordlines 152. In the plan view of FIG. 1B, bitlines 140 are shown running under multiple stacks of capacitors 120. Each bitline 140 is coupled to source structure 114 over bitline 140. Each bitline 140 couples the multiple source structures 114 of transistors 110 corresponding to the stacks of capacitors 120 over that bitline 140.

Vias 131, 151 and first electrodes 121 are shown as rectangles, but may have other, e.g., circular, cross-sections. In some embodiments, cross-sections of vias 131, 151 and first electrodes 121 have substantially rectangular cross-sections with rounded corners.

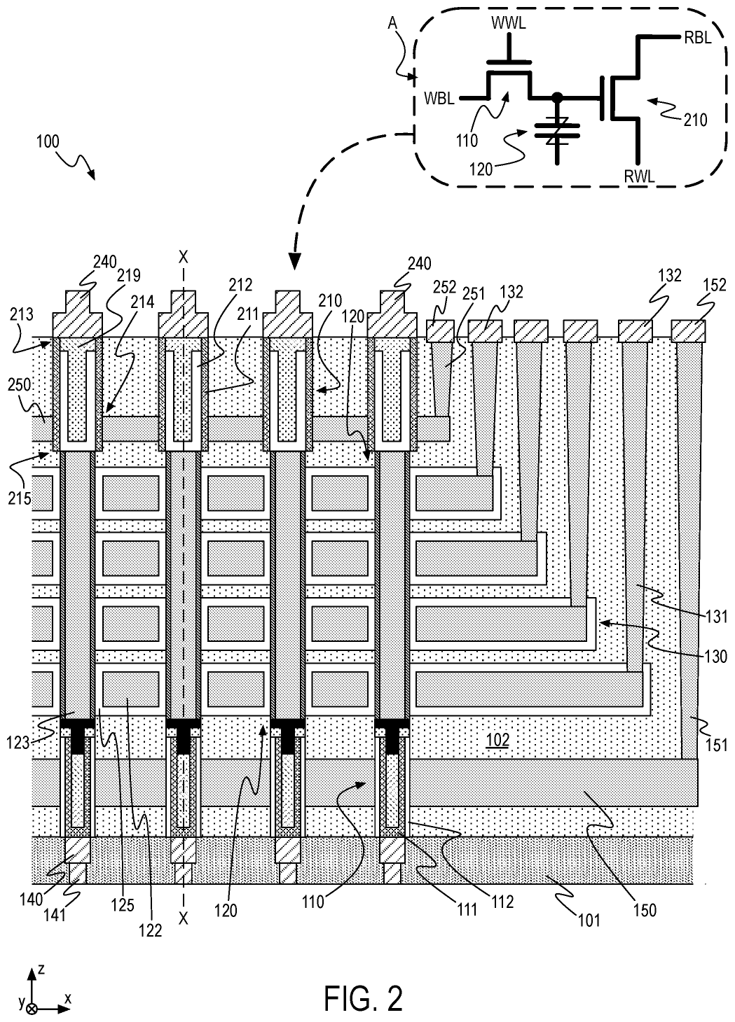

FIG. 2 illustrates a cross-sectional profile view of IC device 100 having arrays of write and read transistors 110, 210 with vertical channel regions 111 under and over corresponding vertical stacks of capacitors 120 with shared vertical electrodes 121, in accordance with some embodiments. Device 100 is similar to the embodiment of FIGS. 1A, 1B, but additionally has an array of read transistors 210 over the array of first electrodes 121, as well as corresponding read bitlines 240 (running parallel in the y direction) and read wordlines 250, 252. Read wordlines 250, 252 are coupled by read wordline via 251. Read transistors 210 are channel-all-around (CAA) transistors 210. With added elements for read operations (but in a same die area), transistors 110, bitlines 140, and wordlines 150, 152 may be write transistors 110, write bitlines 140, and write wordlines 150, 152 dedicated to write operations. View A shows a schematic representation of a portion of an embodiment of device 100. For example, view A shows the array of storage capacitors 120 connected between write and read access transistors 110, 210 in a gain-cell configuration.

Transistors 210 may have similarities with transistors 110, e.g., transistors 110, 210 are coaxial aligned and symmetric about axis X. Read transistors 210 may have differences from transistors 110, as first electrode 121 of a stack of capacitors 120 is coupled to a gate structure (including a gate dielectric 212) of CAA transistor 210. Gate dielectric 212 (and so the gate structure) is in direct contact with first electrode 121. Transistor 210 has channel region 211 around, and coaxial with, gate dielectric 212. Channel structure or region 211 surrounds the gate structure of transistor 210, including gate dielectric 212. Transistor 210 and channel region 211 are over first electrode 121, and first electrode 121 is between transistors 110, 210 (and between channel regions 111, 211). Transistor 210 and channel region 211 are coaxial with first electrode 121. Transistor 210 and gate dielectric 212 are coupled to first electrode 121. Transistors 210 are in a matching array over the array of transistors 110 such that each first electrode 121 is vertically aligned with, and between, corresponding channel regions 111, 211 and transistors 110, 210 in the lower and upper arrays of transistors 110, 210. Transistor 210 and channel region 211 have a vertical centerline on and aligned with axis X, aligned with vertical centerlines of first electrode 121 and transistor 110 and channel region 111.

Transistors 210 may have gate structures 215 (e.g., including gate dielectric 212 adjacent first electrodes 121 of capacitor 120 stacks), drain structures 213 (e.g., adjacent channel regions 211 and read bitlines 240), and source structures 214 (e.g., adjacent channel regions 211 and read wordline 250). Read wordline 250 couples source structures 214 of read transistors 210. Read bitlines 240 couples drain structures 213 and read transistors 210. Write wordline 150 couples gate electrodes 115 (including gate dielectrics 112) of write transistors 110. Write bitlines 140 couple source structures 114 and write transistors 110. During read operations, the bit (e.g., polarization) stored in any selected capacitor 120 (e.g., selected by a unique combination of both the plateline 130 corresponding to the capacitor 120 and the read wordline 250) causes the corresponding upper channel region 211 (and read transistor 210) to conduct (or not conduct), which passes (or blocks) the transmission of the signal on read wordline 250 on to read bitline 240. The signal (e.g., a read enable) on read wordline 250 also determines whether the bit (e.g., polarization) stored in any selected capacitor 120 will enable conduction of read transistor 210.

Transistors 110, 210 may be of any suitable type. For example, either or both may be GAA or CAA transistors. In the exemplary embodiment, CAA read transistors 210 are coaxially aligned over GAA write transistors 110. CAA read transistors 210 have a slightly wider footprint than GAA write transistors 110, which enables the contacting of gate dielectrics 212 by first electrodes 121 while maintaining the separation or isolation of upper channel regions 211 from first electrodes 121.

Dedicated write and read transistors 110, 210 under and over capacitor 120 stacks (and dedicated write and read bitlines 140, 240 and wordlines 150, 250) facilitate decoupled read and write operations, which allows for more efficient read operations (e.g., quicker current sensing on read-only bitlines) and reduced time and power requirements for write operations (e.g., less precharging of write-only bitlines).

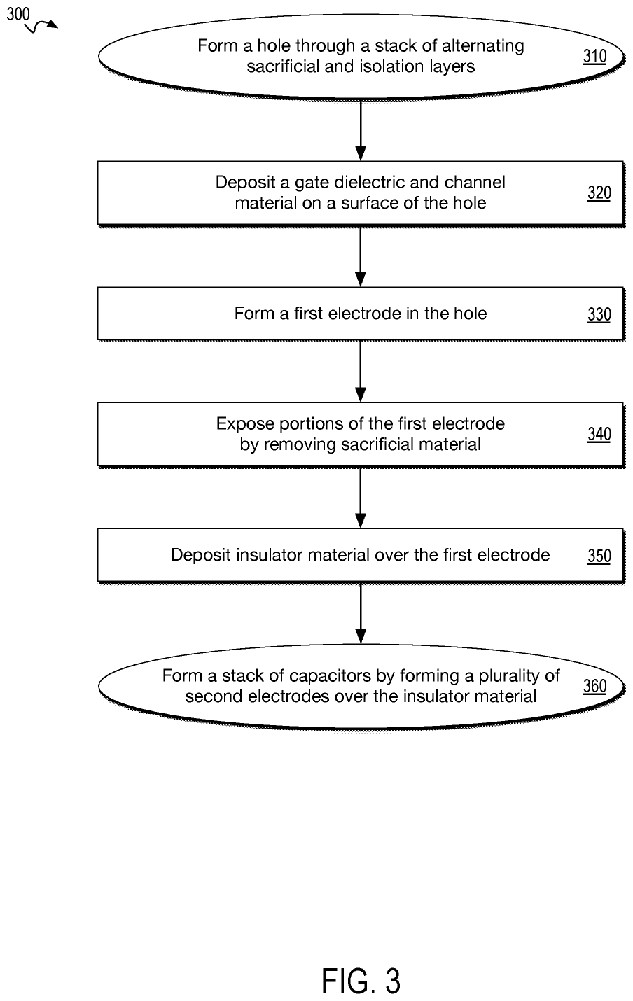

FIG. 3 is a flow chart of methods 300 for forming an array of capacitors having a shared electrode vertically aligned with a corresponding access transistor, in accordance with some embodiments. Methods 300 include operations 310-360. Some operations shown in FIG. 3 are optional. Additional operations may be included. FIG. 3 shows an example sequence, but the operations can be done in other orders as well, and some operations may be omitted. Some operations can also be performed multiple times before other operations are performed. For example, multiple holes may be formed in the stack of layers before any other subsequent operations. Some operations may be included within other operations so that the number of operations illustrated FIG. 3 is not a limitation of the methods 300.

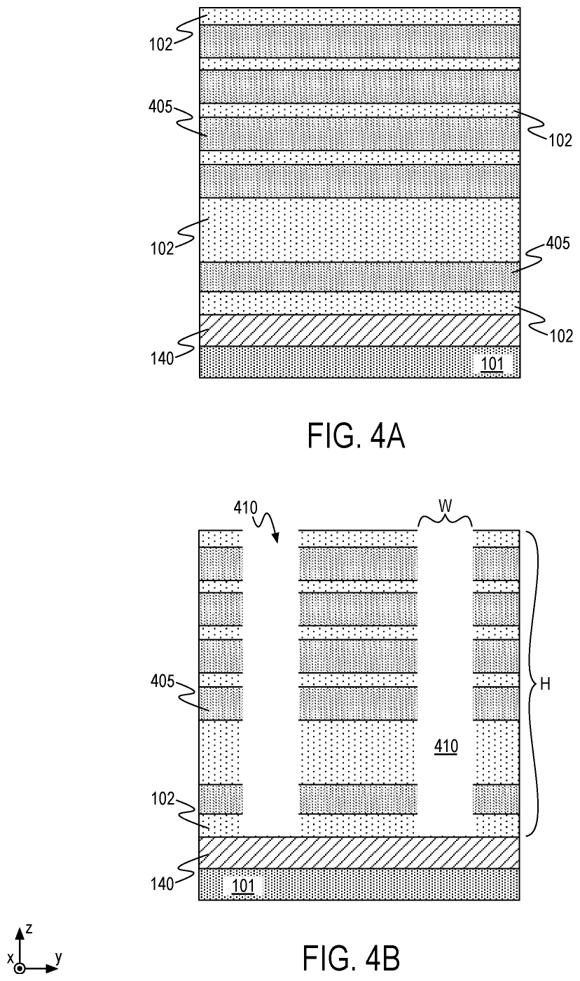

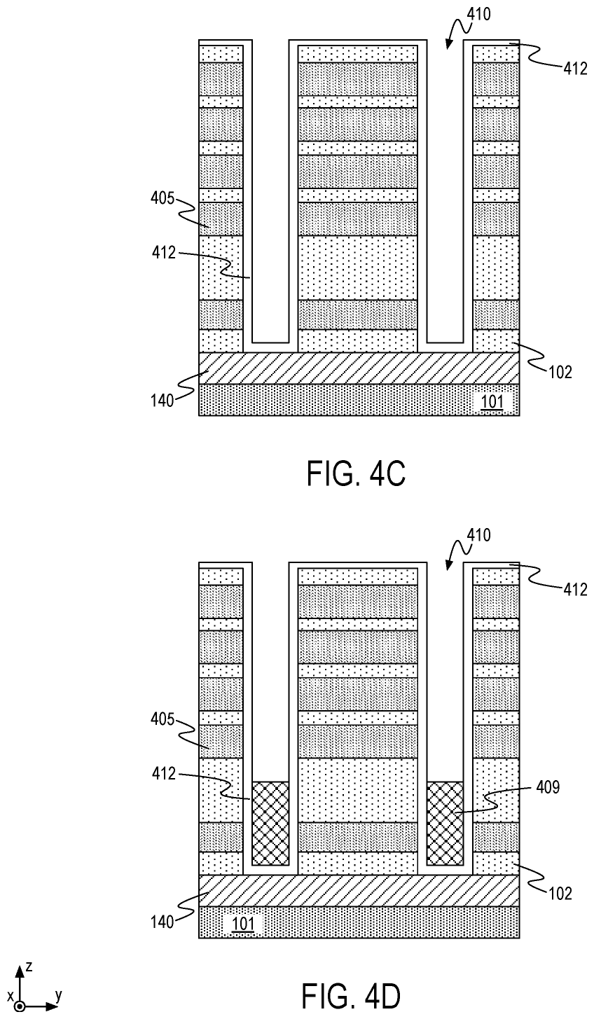

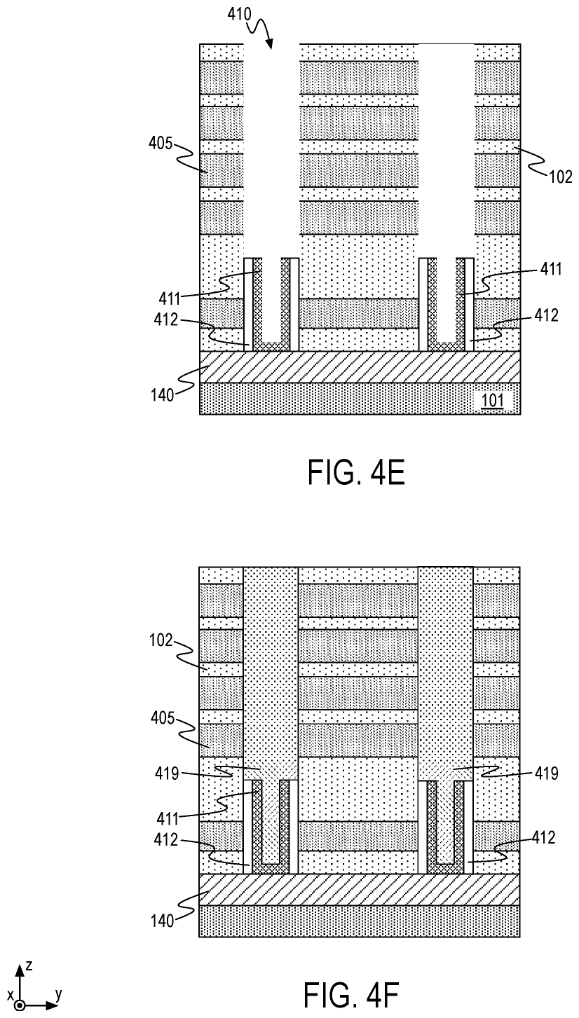

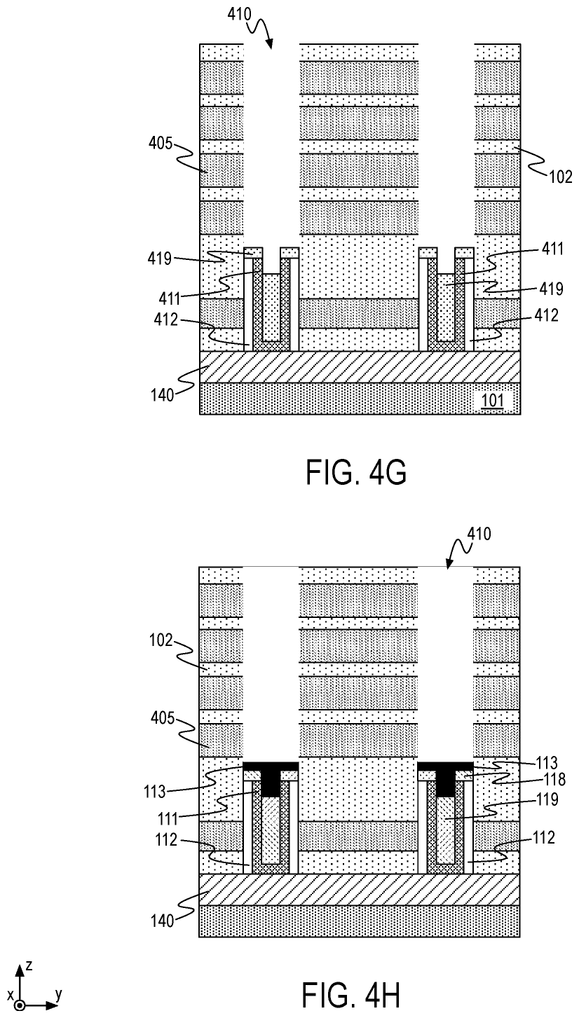

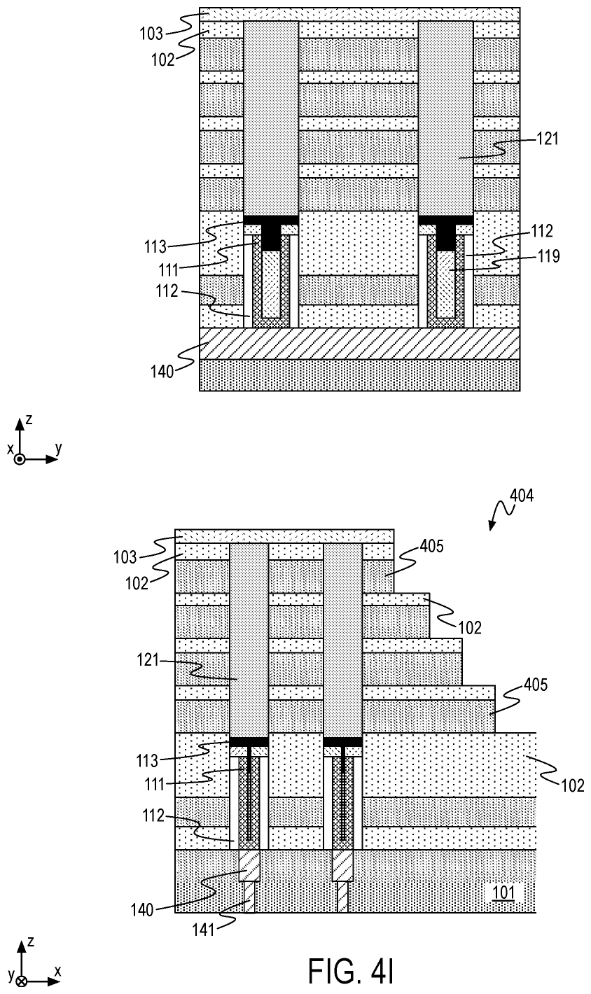

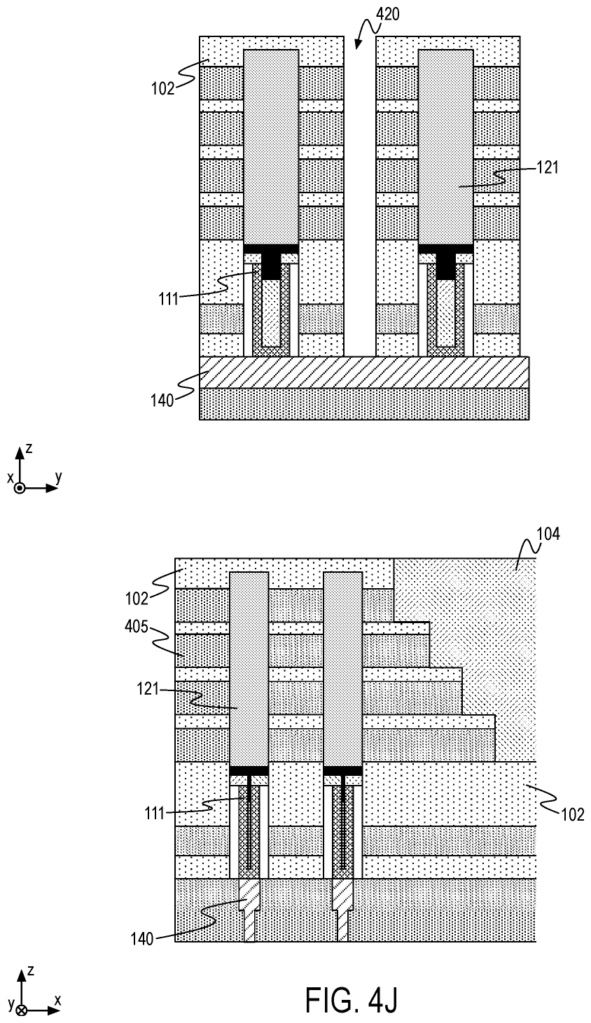

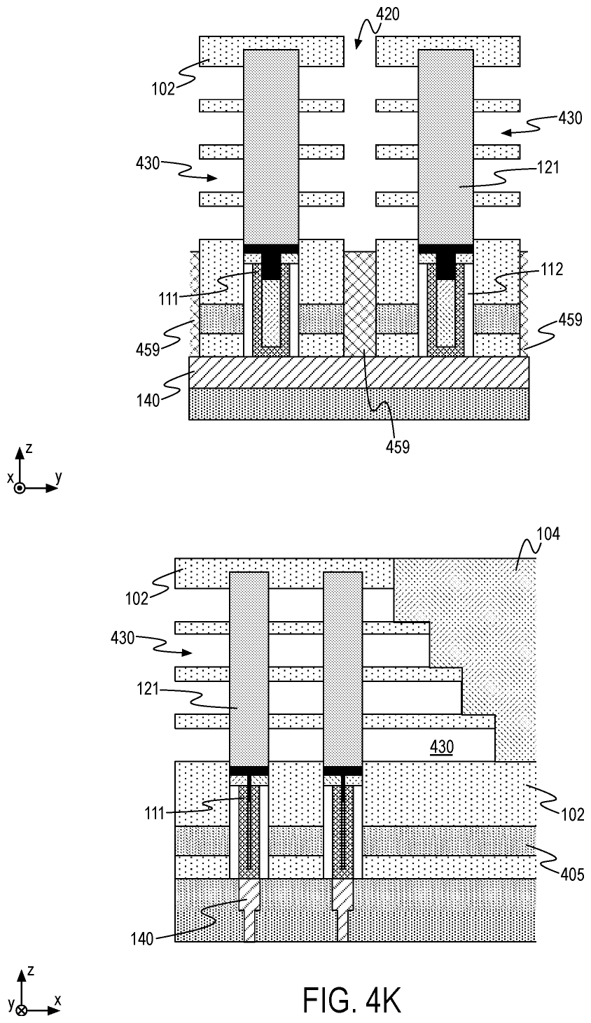

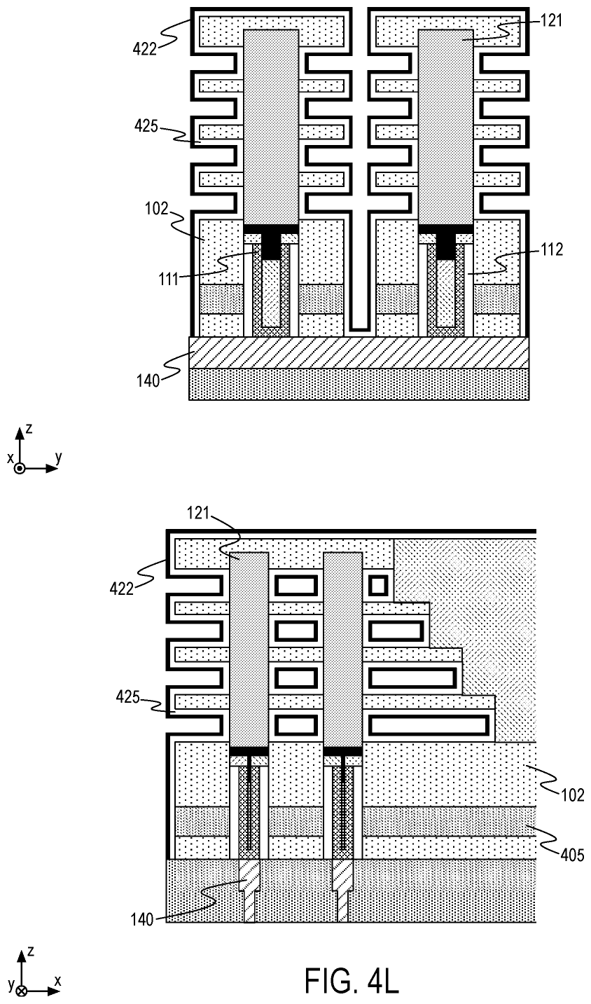

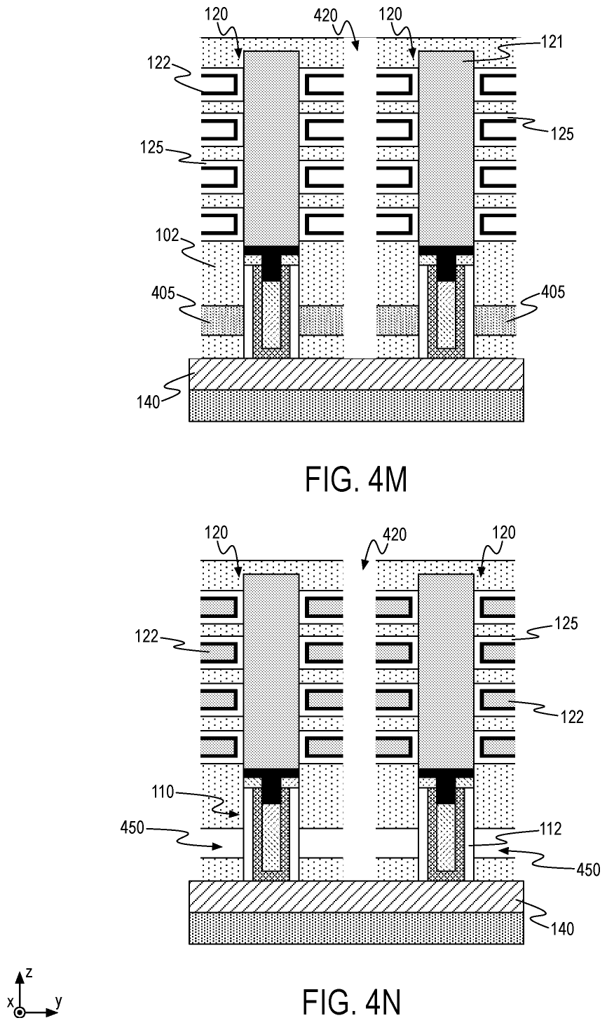

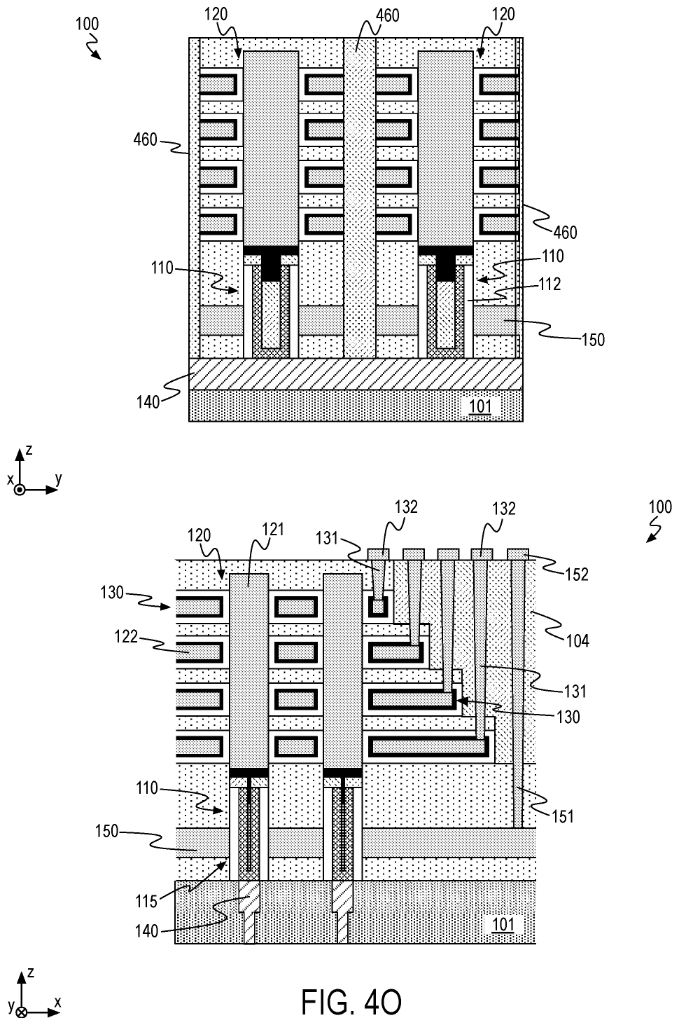

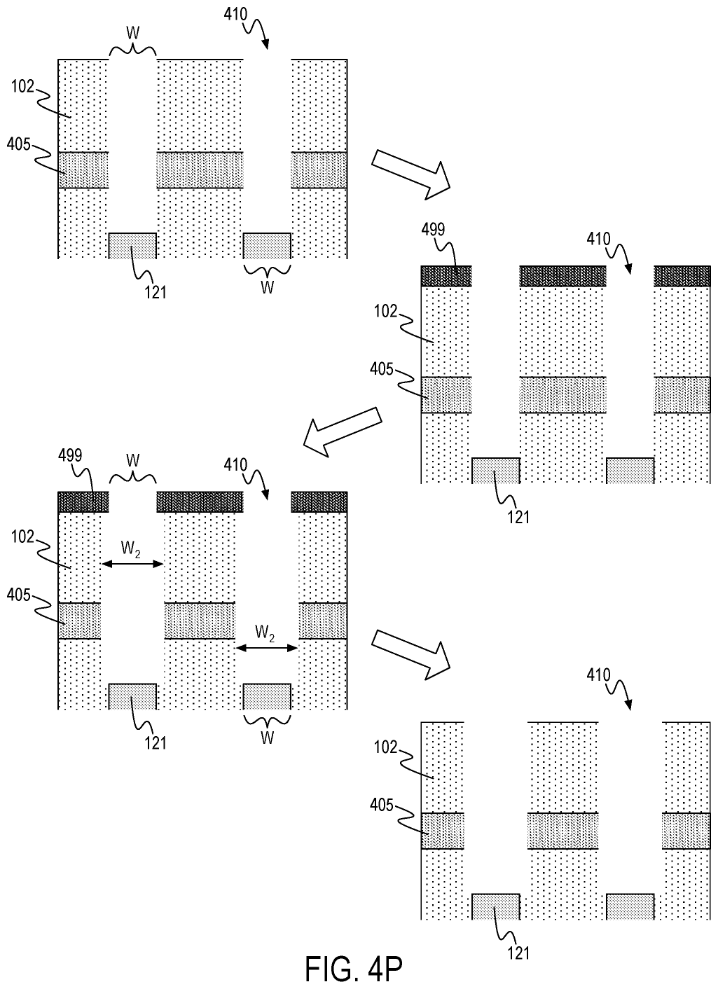

FIGS. 4A, 4B, 4C, 4D, 4E, 4F, 4G, 4H, 4I, 4J, 4K, 4L, 4M, 4N, 4O, and 4P illustrate cross-sectional profile views of device 100 with a 3D array of capacitors 120 having shared vertical electrodes 121 and access transistors 110 vertically aligned, at various stages of manufacture, in accordance with some embodiments. Some figures include cross sections of both fin-cut (e.g., y-z plane) and poly-cut (e.g., x-z plane) views.

Returning to FIG. 3, methods 300 begin at operation 310 with forming a hole through (e.g., an opening in) a stack of alternating layers of sacrificial material and isolation layers. The alternating stack of layers may be received as is or formed. The stack of layers may be formed by any suitable means and of any suitable materials. The stack of layers may be formed such that an etch selectivity exists between the sacrificial layers and isolation layers. The isolation layers may be retained to isolate adjacent capacitors and conductive lines (e.g., platelines and wordlines), so the isolation layers may be or include a sufficiently insulating (e.g., electrically insulating) material, such as a low-K dielectric material. The sacrificial layers may be removed to open up space for capacitors and conductive lines. As the sacrificial layers may be entirely removed, many materials may be suitable. For example, even conductive sacrificial layers may be formed. However, a stack of alternating dielectric layers may advantageously enable the forming of a high-aspect ratio hole. In many embodiments, alternating oxide (e.g., a silicon oxide, such as SiO₂, or aluminum oxide, such as Al₂O₃, etc.) and nitride (e.g., a silicon nitride, such as Si₃N₄) layers may provide an etch selectivity between the alternating layers and also allow for a high-aspect ratio etch through the stack. A hardmask layer may be over the stack of alternating sacrificial and isolation layers.

The stack of layers may be formed (or received) over a substrate, such as a semiconductor or insulator wafer or die, e.g., much as described of substrate 101 (at least) in FIG. 1A. The stack of layers may be over a metallization structure (such as a conductive line or via) in the substrate, a structure that may eventually couple and electrically connect the array of capacitors, e.g., through a vertically aligned access transistor. For example, a conductive line may be a bitline that, after the transistor(s) and capacitor stack has been formed, carries data (e.g., bits) to be read from and/or written to one or more stacks of storage capacitors. The multiple layers may be employed in the formation of multiple, adjacent stacks of capacitors aligned over and along the same bitline. Multiple (e.g., parallel) bitlines may be in the substrate such that a 2D array of transistors may be formed over the bitlines (e.g., in rows in the x and y directions). The bitlines may be just above existing transistors, for example, in logic devices, or within a layer interconnecting parallel legs of a logic device, such as a gate or inverter. The bitlines may be elsewhere in interconnect layers, e.g., in higher layers. Other configurations may be employed.

The hole may be formed by a vertical etch through the layers. Any suitable means may be used to form the opening. An etch may be a high-aspect ratio etch, e.g., with a depth 10 times the width or greater. In some embodiments, an anisotropic dry etch, such as a reactive-ion etch (RIE), is used. In some embodiments, a deep RIE (DRIE) is used. In some embodiments, the etch has a depth 50 times the width. Such a deep and narrow etch may enable a tall, narrow stack (e.g., of many stacked capacitors with small dimensions). Such a deep and narrow etch, and with substantially vertical sidewalls, may provide relatively uniformly optimal capacitors (e.g., with same dimensions, such as inner and outer diameters of the insulator material), etc. The sidewalls may have a slight taper, e.g., such that an upper diameter of the hole is slightly greater than a lower diameter of the hole.

In some embodiments, forming the hole or opening exposes a metallization structure below the stack of layers. For example, an etch through the stack may form the opening over and down to a bitline to be coupled to an access transistor. In some embodiments, multiple holes are etched through the stack. In some such embodiments, the holes each expose a bitline corresponding to a stack of capacitors. In some such embodiments, multiple bitlines each are exposed by multiple holes.

FIG. 4A illustrates a stack of alternating layers of dielectric 102 and sacrificial material 405 over bitline 140 (e.g., in metal0, running in the y direction) in substrate 101. Dielectric 102 may be a low-K insulator as described elsewhere herein (e.g., at least at FIG. 1A). Sacrificial material 405 may be any suitable material, such as a material with a different composition than dielectric 102, and such that an etch selectivity exists between dielectric 102 and sacrificial material 405, enabling a subsequent removal of sacrificial material 405 and retention of dielectric 102. For example, dielectric 102 may include any suitable oxide, carbide, oxycarbide, etc., and sacrificial material 405 may include any suitable nitride, oxynitride, etc., including metal-nitrides. Advantageously, suitable dielectric 102 and sacrificial material 405 are chosen such that a high-aspect ratio etch through the alternating layers may be achieved.

FIG. 4B shows alternating layers of dielectric 102 and sacrificial material 405 with high-aspect ratio openings or holes 410 in the layer stack, e.g., after an operation 310 of methods 300. Bitline 140 is exposed at the bottom of holes 410. Multiple holes 410 are shown over bitline 140 in the fin-cut (e.g., y-z plane) perspective of FIG. 4B. Other holes 410 may be on bitline 140 (e.g., to either side of holes 410 shown), and other bitlines 140 (e.g., with more holes 410) may be in front of or behind the viewing plane. Poly-cut (e.g., x-z plane) views will be shown in other figures.

Holes 410 may have an aspect ratio of 50-to-1, e.g., with a height H equal to 50 times a width W. In some embodiments, holes 410 have an aspect ratio of 10-to-1. Hole 410 through the stack may enable the self-aligned forming of a transistor and a stack of capacitors, for example, with the transistor at the bottom (and/or top) of hole 410, under (and/or over) a stack of capacitors in the same hole. Such a self-aligned process may eliminate multiple lithography operations to align these multiple elements (e.g., the transistor(s) and multiple capacitors).

Returning to FIG. 3, methods 300 continue with depositing a gate dielectric and a channel material in the hole at operation 320. A transistor may be formed with the gate dielectric and channel materials. The gate dielectric and channel materials may be deposited over many holes in the stack such that multiple transistors (e.g., a 2D array of transistors) are formed concurrently. The gate dielectric and channel materials may be deposited one over the other, e.g., conformally over sidewalls of the hole in the stack of layers. As such, the gate dielectric and channel materials may be deposited in coaxial layers (e.g., coaxial about the axis of the hole), with the first-deposited material on the outside and laterally surrounding the second-deposited material, which is over the outer, first-deposited material and closer to the hole axis.

The operation and type of the eventual, yet-to-be formed transistor will depend on the order of deposition of the gate dielectric and channel materials. For example, a GAA transistor may be formed by forming a gate structure (including the gate dielectric) on an inner sidewall of the hole, and forming other transistor elements (e.g., the channel region) over, and internal to, the gate dielectric. In some embodiments, when depositing the gate dielectric and the channel material, the gate dielectric is deposited first, over a sidewall of the hole, and the channel material is deposited over the gate dielectric and a conductive line at the bottom of the hole. A stack of capacitors may then be formed over the transistor, which may provide access to the capacitor array. In some embodiments, a stack of capacitors may have two access transistors, for example, with access transistors under and over the storage capacitors. In some such embodiments, a GAA transistor is formed at the bottom of the hole, a stack of capacitors is formed over the GAA transistor, and a CAA transistor is formed over the stack of capacitors. A CAA transistor may be formed by forming a channel region on an inner sidewall of the hole, and forming a gate structure over, and internal to, the channel material. In some embodiments, when depositing the gate dielectric and channel materials, the channel material is deposited over a sidewall of the hole and the gate dielectric is deposited over the channel material and a shared, inner (first) electrode of a capacitor stack.

In embodiments with two transistors, either or both transistors may be GAA or CAA transistors. Forming a GAA transistor at the bottom of the hole and a CAA transistor over a first electrode of the capacitor stack (e.g., at a top of the hole) enables the functionality described at FIG. 2. For example, forming a GAA transistor over a bitline at the hole bottom allows gate dielectric material to separate the wordline (and gate electrode) from the channel material, as well as allowing the channel material to be formed over, and internal to, the gate dielectric, and to contact the bitline. Forming a CAA transistor over a first electrode of the capacitor stack allows for the stored bit (e.g., a certain polarization) on the first electrode to control conduction of the upper transistor, e.g., by the gate connection to the first electrode.

The gate dielectric material may be any suitable material and may advantageously be a high-K dielectric (e.g., as described at FIG. 1A) capable of conformal deposition, such as on sidewalls of the hole in the layer stack and/or over a channel material. The gate dielectric material may be deposited by any suitable means. In at least some embodiments, the means used is advantageously capable of deposition at low temperatures (e.g., in a BEOL environment), such sputtering or physical vapor deposition (PVD) and ALD. In some embodiments, the gate dielectric may be further processed, e.g., in doping or annealing operations, etc.

The channel material may be any suitable material (some examples of which are described at FIG. 1A) and may advantageously be capable of conformal deposition, such as on sidewalls of the hole in the layer stack and/or over a gate dielectric material. The channel material may be deposited by any suitable means. The deposition may advantageously be area-selective growth of a high-quality film. The deposition may employ pulsed-laser deposition. In at least some embodiments, the means used is advantageously capable of deposition at low temperatures (e.g., in a BEOL environment), such PVD and ALD. In some embodiments, further processing, e.g., doping or annealing, may improve a characteristic of the channel material (e.g., conductivity).

A hardmask material may be employed, for example, deposited in the hole, to control a height of the layers on a sidewall of the hole, and so to control a height of the transistor. The hardmask may be deposited (e.g., anisotropically) over the gate dielectric and/or channel materials in the hole to form a hardmask plug of the desired height in the hole. The gate dielectric and/or channel materials may then be removed, e.g., selectively, to again expose the alternating layers as a sidewall of the hole above the hardmask plug, but to retain the gate dielectric and/or channel materials masked by the hardmask plug. The hardmask plug may then be removed, and the gate dielectric and/or channel materials may be exposed. An anisotropic etch of the gate dielectric and/or channel materials may be performed before or after the hardmask plug is formed, for example, to expose a conductive feature (e.g., a bitline or capacitor first electrode) at the bottom of the hole before depositing a next layer.

In some embodiments, a structural plug, for example, of an insulator material, is formed between the channel material and gate dielectric layers before subsequent materials and structures (such as a drain contact) are formed in the hole and over, e.g., the channel material. In some embodiments, an insulator material is formed over an upper surface of the gate dielectric layer before a drain contact is formed in the hole, e.g., as an isolation or interface layer between the gate dielectric material and the drain contact. The insulator material may be formed in the hole and any excess insulator material removed to expose channel material for contacting by a drain contact.

FIG. 4C illustrates a stack of alternating layers of dielectric 102 and sacrificial material 405 with holes 410 and a gate dielectric layer 412 conformally over the layers, holes 410, and bitline 140 at the bottom of holes 410. In some embodiments, gate dielectric layer 412 is not present, and a channel material layer (not shown) is conformally over the layers and holes 410.

FIG. 4D shows sacrificial hardmasks 409 are over gate dielectric layer 412 in holes 410 in a stack of alternating layers of dielectric 102 and sacrificial material 405. In some embodiments, sacrificial hardmasks 409 are in contact with bitline 140, and no gate dielectric layer 412 is present between hardmasks 409 and bitline 140. For example, in some embodiments, hardmasks 409 are in contact with bitline 140, and gate dielectric layer 412 is present only over sidewalls of holes 410.

FIG. 4E illustrates channel material layer 411 and gate dielectric layer 412 over sidewalls of holes 410 in a stack of alternating layers of dielectric 102 and sacrificial material 405, e.g., after operation 320 of methods 300. Channel material layer 411 may have been formed much as gate dielectric layer 412. Channel material layer 411 is in contact with bitline 140 between gate dielectric layers 412 and sidewalls of holes 410. Sacrificial hardmasks 409 are not present, and layers 411, 412 are up the sidewalls to a desired height, e.g., about the height of sacrificial hardmasks 409 in FIG. 4D.

FIG. 4F shows an insulator material 419 over layers 411, 412 (including over an upper surface of gate dielectric layer 412) and between and within inner channel material layer 411. Insulator material 419 is to the top of stack of alternating layers of dielectric 102 and sacrificial material 405, and holes 410 are absent.

FIG. 4G illustrates channel material layer 411 exposed and holes 410 in the stack of alternating layers of dielectric 102 and sacrificial material 405, for example, after excess insulator material 419 has been removed, e.g., by a recess etch. Insulator material 419 is over an upper surface of layers 411, 412 and between and within inner channel material layer 411, but with an upper, inner portion of channel material layer 411 exposed over insulator material 419.

Returning to FIG. 3, methods 300 continue at operation 330 with forming a first electrode in the hole. With a footprint of the first electrode defined by sidewalls of the same hole, the first electrode is coaxial with the channel material and gate dielectric, which are both symmetric about a same axis of the hole. The material of a first electrode may be deposited in many holes in the stack such that multiple electrodes (e.g., a 2D array of first electrodes) are formed concurrently. An eventual 3D array of capacitors may include the 2D array of first electrodes and a stack of capacitors around (and including) each of the first electrodes.

The first electrode may be formed by any suitable means and of any suitable material(s), e.g., conductive materials, such as metals. The first electrode may include multiple materials, for example, contact metals, liner metals, fill metals, etc. In some embodiments, the first electrode is continuous with a source or drain contact or a gate electrode of an adjacent transistor. For example, a metallic drain contact may be deposited over a channel region (or drain region of a semiconductor material), and a vertical electrode of the same or a different metal through the alternating stack of layers may be coaxial and vertically aligned with the drain contact. A drain contact may cap a transistor and interface between a semiconductor material and any metal(s) (or other conductive materials) of the first electrode, e.g., deposited in the hole over the channel material and gate dielectric. An interface with a semiconductor material may be as a work-function metal, a barrier metal, etc. In some embodiments, a drain contact is deposited isotropically over the bottom of the hole, for example, over the channel material and gate dielectric.

In some embodiments, a liner or barrier metal (or other material) is deposited conformally over the drain contact (or the channel material and gate dielectric) and the sidewalls of the hole. The liner material may be a metal or any other conformally deposited conductive material, such as a 2D material. The liner material may be chosen for its compatibility with a fill or bulk metal, e.g., as a barrier layer or a seed layer for subsequent metal growth. In many embodiments, liner materials include at least one of titanium, ruthenium, tantalum, tungsten, or molybdenum. A liner material may be deposited by any suitable means, e.g., conformally by ALD, which may allow for selective deposition.

A fill or bulk metal may be deposited in the hole over and within the liner material. A fill metal may be any suitably conductive material(s), such as tungsten, titanium, nitrogen (e.g., in a titanium nitride or nitride of another metal), ruthenium, molybdenum, cobalt, copper, etc. A fill metal may be deposited in any suitable fashion, for example, grown from a liner material seed layer. In some embodiments, no liner material is deposited. In some embodiments, a fill metal, or a metal without a liner material, is formed anisotropically in the hole, e.g., built up from the bottom (over the channel material, etc.).

Etches may be made into and/or through the stack of alternating layers, e.g., following the filling of the holes with the formation of first electrodes. In some embodiments, isolation etches are made between adjacent stacks of first electrodes and transistors. Such an etch may form one or more holes through the stack of alternating layers, which may expose the sacrificial layers for selective removal. In some embodiments, portions of dielectric and sacrificial layers are removed in preparation for forming vertical interconnects between the stacks of horizontal lines and interconnect layers above.

FIG. 4H shows drain structure 113, including a metal contact over channel region 111, high-K dielectric 112, and insulating plug 119, with isolation 118 separating drain structure 113 and gate dielectric 112. Drain structure 113, channel region 111, high-K dielectric 112, and insulating plug 119 are all coaxial in hole 410. Drain structure 113 and high-K dielectric 112 are vertically aligned in hole 410.

FIG. 4I illustrates a stack of alternating layers of dielectric 102 and sacrificial material 405 with first electrodes 121 (and no holes 410) over channel region 111, high-K dielectric 112, and drain structure 113, e.g., after operation 330 of methods 300. FIG. 4G shows the stack with cross sections of both fin-cut (e.g., y-z plane) and poly-cut (e.g., x-z plane) views.

A cap layer of dielectric 103 is over first electrodes 121. Dielectric 103 may have the same or a different composition than dielectric 102. Dielectric 103 may isolate first electrodes 121 from other conductive structures, such as interconnects in layers above first electrodes. First electrodes 121 are coaxial with channel region 111, high-K dielectric 112, and drain structure 113. First electrodes 121 are vertically aligned with high-K dielectric 112 and drain structure 113. In some embodiments, first electrodes 121 are continuous with a contact of drain structure 113, e.g., without a discernable interface between a contact metal and fill metal through alternating layers.

In the view showing the x-z plane, a staircase opening 404 is within the alternating layers of dielectric 102 and sacrificial material 405. Upper layers of dielectric 102 and sacrificial material 405 are shorter than lower layers of dielectric 102 and sacrificial material 405, and upper surfaces of lower layers of dielectric 102 and sacrificial material 405 extend beyond upper surfaces of upper layers of dielectric 102 and sacrificial material 405. Sacrificial material 405 may be removed and replaced by conductors, and such a configuration allows for vertical interconnections upwards from the portions of layer extending beyond the layers above.

Also visible in the x-z plane are multiple bitlines 140 and vias 141 in substrate 101 and under first electrodes 121, coupled to channel regions 111. Multiple first electrodes 121 are in a 2D array of first electrodes 121, with multiple bitlines 140 and multiple first electrodes 121 on each bitline 140.

FIG. 4J shows (in the y-z plane) an isolation opening 420 between adjacent first electrodes 121 and through the stack of alternating layers of dielectric 102 and sacrificial material 405. Sacrificial material 405 is exposed between adjacent first electrodes 121 at isolation opening 420.

FIG. 4J illustrates (in the x-z plane) dielectric 104 over the staircase configuration of dielectric 102 and sacrificial material 405 layers. Dielectric 104 may have the same or a different composition than dielectric 102.

Returning to FIG. 3, methods 300 continue with exposing portions of the first electrode between isolation layers by removing sacrificial material at operation 340. Sacrificial material may be selectively removed by an isotropic etch, for example, by utilizing the previously described etch selectivity between the alternating layers of dielectric and sacrificial materials. Such a selective etch may retain the dielectric layers in the previously alternating stack of layers. The first electrode may be exposed at each level of a removed sacrificial layer. Each removal of a sacrificial layer opens up space for a storage capacitor (e.g., around the first electrode, at an exposed area) and associated lines coupling the capacitors. In embodiments with multiple first electrodes, removing the sacrificial material may concurrently expose similar (e.g., aligned) portions of the multiple first electrodes between the retained dielectric layers.

In some embodiments, a hardmask material is deposited in holes in the stack of layers prior to selectively removing the sacrificial material. Such a hardmask may allow for removing a first portion of sacrificial material and temporarily retaining a second portion of sacrificial material. The hardmask may be removed after the first portion of sacrificial material is selectively removed. A dielectric material, such as a ferroelectric material, may then be deposited before the temporarily retained second portion of sacrificial material is selectively removed.

FIG. 4K shows openings 430 between retained layers of dielectric 102. Sacrificial material 405 is absent above, e.g., channel regions 111. Sidewalls of first electrodes 121 are exposed at openings 430, which surround first electrodes 121 at the level of openings 430.

Hardmasks 459 are in openings 420 between first electrodes 121. Sacrificial material 405 is present adjacent gate dielectric 112. Hardmasks 459 mask sacrificial material 405 adjacent gate dielectric 112.

Returning to FIG. 3, methods 300 continue at operation 350 with depositing an insulator material over the first electrode. The insulator material may be a dielectric material or any other material capable of acting as a storage medium, e.g., by storing charge in a storage capacitor. In some embodiments, the deposited insulator material is a ferroelectric material, and the ferroelectric material is deposited between isolation layers and over exposed portions of the first electrode. In embodiments with multiple first electrodes, insulator material may be deposited concurrently over exposed portions of the multiple first electrodes.

The insulator material may be formed by any suitable means. Advantageously, the insulator material may be deposited conformally in thin layers at low temperatures and low cost. In some embodiments, the insulator material is conformally deposited by ALD. In some such embodiments, the insulator material is deposited at low temperatures (e.g., <250° C.), e.g., at a BEOL. In some embodiments, the insulator material is a 2D material. In some embodiments, the insulator material is epitaxially deposited.

In some embodiments, the insulator material is a ferroelectric material, e.g., a high-K dielectric material in a ferroelectric phase. In some such embodiments, the insulator material is HZO or otherwise includes hafnium, oxygen, and a third material, such as a dopant. In some embodiments, the ferroelectric material includes PZT or another material with a perovskite structure. In some embodiments, the ferroelectric material includes aluminum and nitrogen, e.g., in a wurtzite structure. In some such embodiments, the ferroelectric material also includes scandium. Other ferroelectric materials may be employed.

Methods 300 continue with forming a stack of capacitors by forming a group of second electrodes over the insulator material at operation 360. For example, the second electrodes may be formed as a stack of electrodes with coaxial and vertically aligned inner diameters. Their outer diameters may be indeterminate as the second electrodes may be continuous with conductive lines, e.g., platelines, that couple second electrodes in adjacent stacks. In some embodiments, a stack of capacitors includes a first electrode extending vertically through holes in stacked platelines and an insulator material (e.g., a ferroelectric material) around the first electrode and between the first electrode and each plateline in the stack.

The second electrodes may be formed by depositing a conductive material, such as one or more metals, over the insulating storage material, e.g., a ferroelectric material. In embodiments with multiple first electrodes, conductive material may be deposited (and stacks of second electrodes may be formed) concurrently over insulating storage material on multiple first electrodes. The second electrodes may include layers of different conductive materials. For example, a liner material may be deposited over the insulating storage material, and a fill metal may then be grown over the liner material. In some embodiments, a metal is conformally deposited over a conformal layer of ferroelectric material.

A recess etch may be performed, for example, before forming a fill metal, to remove excess deposited storage and conductive materials. Conformal depositions of the insulating storage and conductive materials may be in continuous layers, including in undesired locations, e.g., in isolation openings between first electrodes and connecting vertically adjacent layers and laterally adjacent first electrodes. For example, an anisotropic isolation etch may be performed between first electrodes to break up continuous, conformal layers of storage and conductive materials.

Depositions of conductive material may be performed multiple times. For example, platelines may be formed after storage material (e.g., ferroelectric material) is deposited on the first electrode(s). In some embodiments, a second portion of sacrificial material may be removed to form other conductors (e.g., one or more wordlines) only after the, e.g., ferroelectric material is deposited.

FIG. 4L illustrates storage material layer 425 and conductive layer 422 conformally over first electrodes 121 and dielectric 102. Conformal storage material layer 425 contacts first electrodes 121 between layers of dielectric 102. Storage material layer 425 and conductive layer 422 are continuous and connect between layers of dielectric 102 and between first electrodes 121.

Hardmasks 459 are absent, but sacrificial material 405 adjacent gate dielectric 112 is covered by layers 422, 425.

FIG. 4M shows stacks of capacitors 120 with insulator material 125 and second electrodes 122 isolated, e.g., after an operation 360 of methods 300. Insulator material 125 and second electrodes 122 are separated between layers of dielectric 102 and each first electrode 121 by an isolation opening 420, e.g., following an anisotropic isolation etch between first electrodes 121. Second electrodes 122 are thin, conformal second electrodes 122 over conformal portions of insulator material 125.

Sacrificial material 405 is unmasked adjacent gate dielectric 112.

FIG. 4N illustrates stacks of capacitors 120 coupled to transistors 110 with exposed gate dielectric 112. Sacrificial material 405 is absent, and cavities 450 are around exposed gate dielectric 112. Stacks of capacitors 120 (e.g., first electrodes 121) are coupled to bitline 140 by transistors 110. Second electrodes 122 include bulk metal within conformal liner metal.

FIG. 4O shows both fin-cut (e.g., y-z plane) and poly-cut (e.g., x-z plane) views of memory device 100. Stacks of capacitors 120 are coupled (at first electrodes 121) to access transistors 110 and bitlines 140. Capacitors 120 in adjacent stacks are coupled by platelines 130. Upper platelines 132 are coupled to lower platelines 130 by vias 131. Wordline 150 and gate electrodes 115 are adjacent gate dielectric 112, and wordline 150 is coupled to gate electrodes 115 of adjacent stacks of capacitors 120 (e.g., in a same word). Upper wordline 152 is coupled to lower wordline 150 by via 151. Vias 131, 151 are through staircase dielectric 104. Adjacent stacks of capacitors 120 (e.g., in separate words) are electrically isolated by isolation dielectric 460.

In some embodiments, access transistors 210 (not shown) are read transistors 210 over capacitor 120 stacks, access transistors 210 are controlled by bits on first electrodes 121, and access transistors 210 electrically connect read bitlines 240 (not shown) to read wordlines 250 (not shown). In some such embodiments, read transistors 210 (not shown) are CAA transistors. Wider CAA read transistors 210 (not shown) may be formed over first electrodes 121 (as shown at FIG. 2) in a self-aligned fashion as described at operation 320. As described at operation 320, wider CAA upper transistors 210 may be formed wide enough to accommodate channel region 211 on both sides of gate dielectric 212 (as shown at FIG. 2). A thin channel material layer 411 may be formed on sidewalls of holes 410 in alternating layers of dielectric 102 and sacrificial material 405. For example, thin channel material layer 411 may be less than 10 nm thick, e.g., 5 nm thick, and allow for gate dielectric 212 to be wider than first electrode 121. Gate dielectric 212 may isolate first electrode 121 from channel region 211.

FIG. 4P illustrates an example sequence of operations to enable wider, self-aligned upper transistors 210 (not shown) to be formed over first electrode 121. First electrode 121 may be coupled to lower transistor 110 (not shown) and a stack of capacitors (not shown) in hole 410 through dielectric 102 and sacrificial material 405. First electrode 121 and hole 410 may have a first width W (as in FIG. 4B). A crown mask 499 (such as a PVD crown or equivalent or other mask material) may be deposited over dielectric 102. Crown mask 499 may be any suitable material, e.g., with an etch selectivity between crown mask 499 and dielectric 102. For example, crown mask 499 may be a conductive material that may deposit on first electrode 121. Holes 410 in dielectric 102 may be widened to a width W₂ (greater than width W) by an etch, e.g., an isotropic dry etch, prior to forming wider, self-aligned upper transistors 210 (not shown) with an operation 320. After holes 410 are widened, crown mask 499 may be removed, e.g., by another etch (for example, selective to the material of crown mask 499).

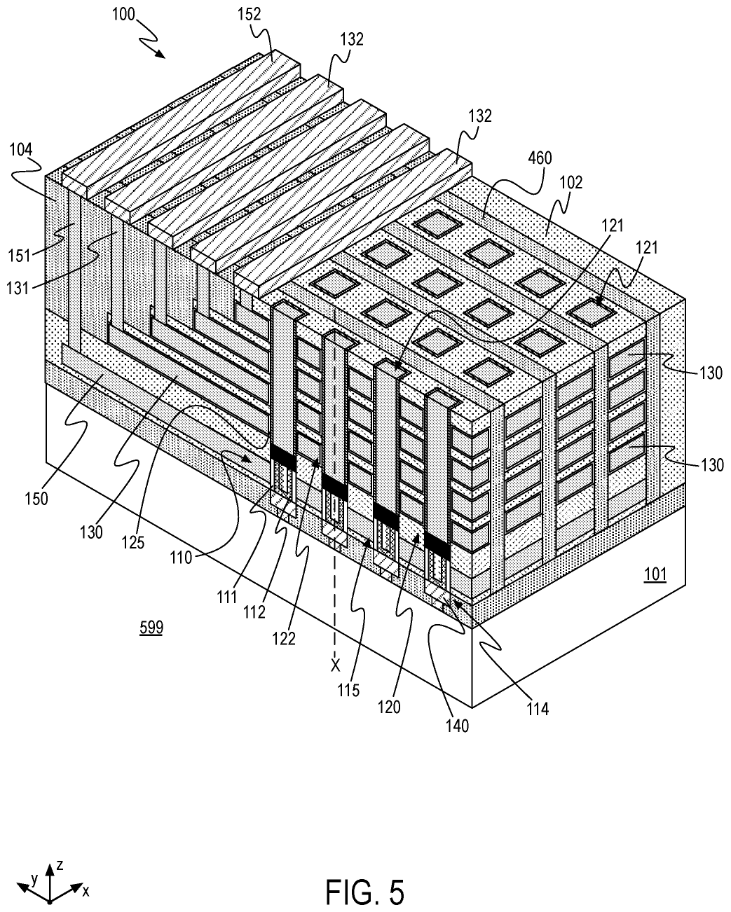

FIG. 5 illustrates a cross-sectional isometric view of memory device 100 having a 3D array of capacitors 120 with 2D arrays of shared vertical electrodes 121 and coaxial access transistors 110 having vertical channel regions 111, in accordance with some embodiments. Device 100 includes an array of transistors 110 in substrate 101 (e.g., an IC die). Transistors 110 include vertical channel regions 111. Device 100 includes an array of capacitor 120 stacks. The stacks of capacitors 120 each include first electrodes 121 coupled to stacks of second electrodes 122. First electrodes 121 are vertical and vertically aligned with, and coupled to, corresponding channel regions 111 in the array of transistors 110. First electrodes 121 are coaxial with corresponding channel regions 111 and gate dielectrics 112, for example, about axis X. In the embodiment of FIG. 5, second electrodes 122 are coupled to corresponding first electrodes 121 by ferroelectric material 125. Each transistor 110 includes gate structures (including gate electrodes 115 and gate dielectrics 112) and source structures 114. Gate electrodes 115 are coupled by wordlines 150, and source structures 114 are coupled by bitlines 140. In some embodiments, a 2D array of transistors 210 (not shown) is over the 2D array of first electrodes 121. In some such embodiments, the 2D array of first electrodes 121 is vertically aligned with, coupled to, and between corresponding channel regions 211 (not shown), 111 in transistors 210, 110.

Device 100 may include additional platelines 132 and/or wordlines 152, e.g., opposite the platelines 132 and wordlines 152 shown. Each capacitor 120 may be independently accessed by a unique combination of platelines 130, bitlines, 140, and wordlines 150.

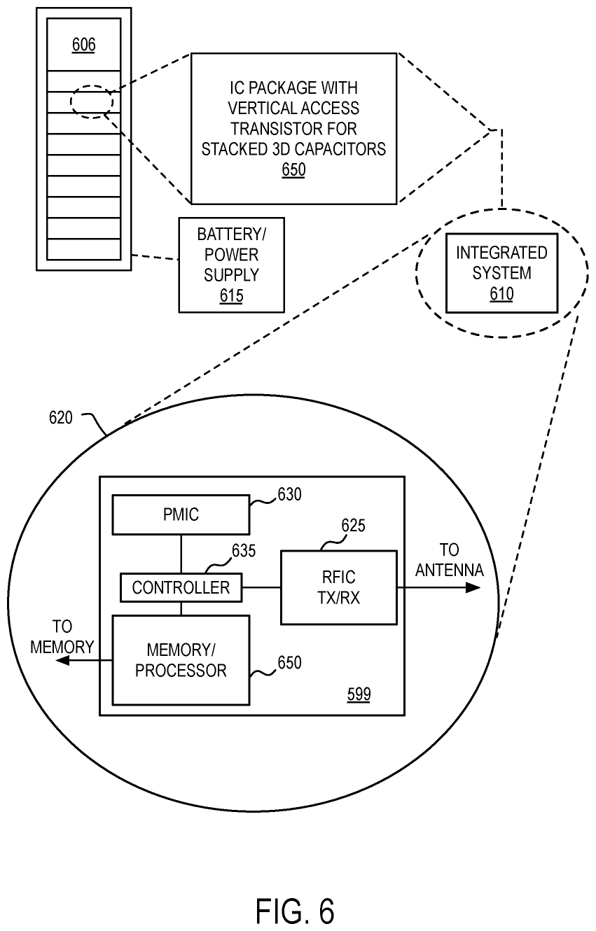

FIG. 6 illustrates a diagram of an example data server machine 606 employing an IC device having a 3D array of storage capacitors with vertical transistors for accessing capacitor stacks coaxial with the transistors, in accordance with some embodiments. Server machine 606 may be any commercial server, for example, including any number of high-performance computing platforms disposed within a rack and networked together for electronic data processing, which in the exemplary embodiment includes one or more devices 650 having stacks of storage capacitors coaxial with vertical access transistors.

Also as shown, server machine 606 includes a battery and/or power supply 615 to provide power to devices 650, and to provide, in some embodiments, power delivery functions such as power regulation. Devices 650 may be deployed as part of a package-level integrated system 610. Integrated system 610 is further illustrated in the expanded view 620. In the exemplary embodiment, devices 650 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 650 is a microprocessor including a static RAM (SRAM) cache memory. As shown, device 650 may be an IC device having a 3D array of storage capacitors with a 2D array of vertically aligned access transistors, as discussed herein. Device 650 may be further coupled to (e.g., communicatively coupled to) a board, an interposer, or a substrate 599 along with, one or more of a power management IC (PMIC) 630, RF (wireless) IC (RFIC) 625 including a wideband RF (wireless) transmitter and/or receiver (TX/RX) (e.g., including a digital baseband and an analog front end module further includes a power amplifier on a transmit path and a low noise amplifier on a receive path), and a controller 635 thereof. In some embodiments, RFIC 625, PMIC 630, controller 635, and device 650 include a 3D array of storage capacitors with vertical transistors for accessing capacitor stacks coaxial with the transistors.

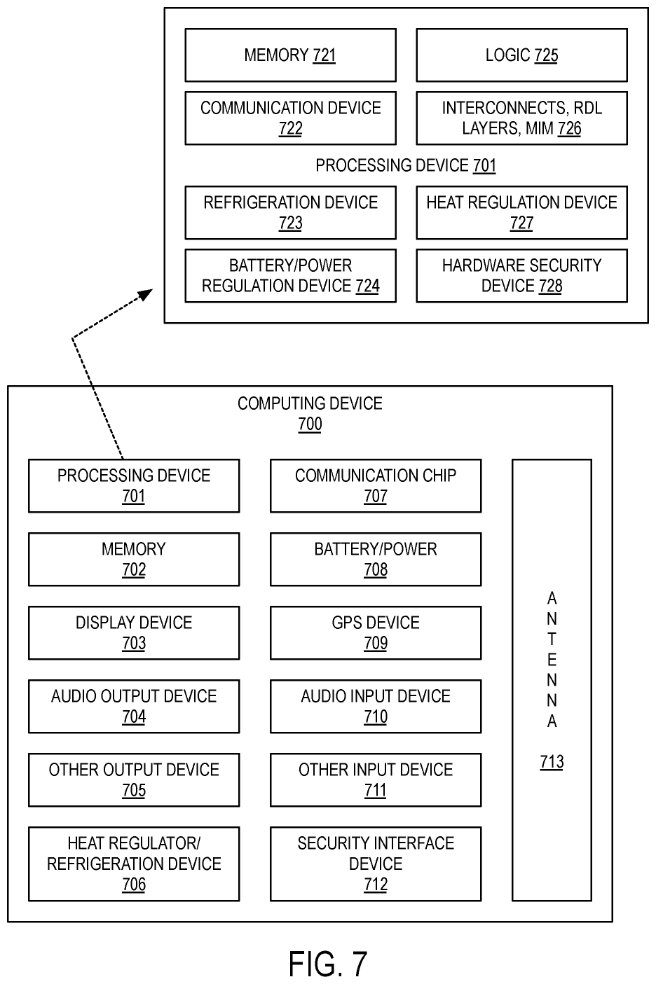

FIG. 7 is a block diagram of an example computing device 700, in accordance with some embodiments. For example, one or more components of computing device 700 may include any of the devices or structures discussed herein. A number of components are illustrated in FIG. 7 as being included in computing device 700, but any one or more of these components may be omitted or duplicated, as suitable for the application. In some embodiments, some or all of the components included in computing device 700 may be attached to one or more printed circuit boards (e.g., a motherboard). In some embodiments, various ones of these components may be fabricated onto a single system-on-a-chip (SoC) die. Additionally, in various embodiments, computing device 700 may not include one or more of the components illustrated in FIG. 7, but computing device 700 may include interface circuitry for coupling to the one or more components. For example, computing device 700 may not include a display device 703, but may include display device interface circuitry (e.g., a connector and driver circuitry) to which display device 703 may be coupled. In another set of examples, computing device 700 may not include an audio output device 704, other output device 705, global positioning system (GPS) device 709, audio input device 710, or other input device 711, but may include audio output device interface circuitry, other output device interface circuitry, GPS device interface circuitry, audio input device interface circuitry, audio input device interface circuitry, to which audio output device 704, other output device 705, GPS device 709, audio input device 710, or other input device 711 may be coupled.

Computing device 700 may include a processing device 701 (e.g., one or more processing devices). As used herein, the term “processing device” or “processor” indicates a device that processes electronic data from registers and/or memory to transform that electronic data into other electronic data that may be stored in registers and/or memory. Processing device 701 may include a memory 721, a communication device 722, a refrigeration device 723, a battery/power regulation device 724, logic 725, interconnects 726 (i.e., optionally including redistribution layers (RDL) or metal-insulator-metal (MIM) devices), a heat regulation device 727, and a hardware security device 728.

Processing device 701 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 700 may include a memory 702, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 702 includes memory that shares a die with processing device 701. This memory may be used as cache memory and may include embedded dynamic random-access memory (eDRAM) with a 3D array of storage capacitors with vertical transistors for accessing capacitor stacks coaxial with the transistors.

Computing device 700 may include a heat regulation/refrigeration device 706. Heat regulation/refrigeration device 706 may maintain processing device 701 (and/or other components of computing device 700) at a predetermined low temperature during operation.

In some embodiments, computing device 700 may include a communication chip 707 (e.g., one or more communication chips). For example, the communication chip 707 may be configured for managing wireless communications for the transfer of data to and from computing device 700. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 707 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 707 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 707 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 707 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 707 may operate in accordance with other wireless protocols in other embodiments. Computing device 700 may include an antenna 713 to facilitate wireless communications and/or to receive other wireless communications (such as AM or FM radio transmissions).

In some embodiments, communication chip 707 may manage wired communications, such as electrical, optical, or any other suitable communication protocols (e.g., the Ethernet). As noted above, communication chip 707 may include multiple communication chips. For instance, a first communication chip 707 may be dedicated to shorter-range wireless communications such as Wi-Fi or Bluetooth, and a second communication chip 707 may be dedicated to longer-range wireless communications such as GPS, EDGE, GPRS, CDMA, WiMAX, LTE, EV-DO, or others. In some embodiments, a first communication chip 707 may be dedicated to wireless communications, and a second communication chip 707 may be dedicated to wired communications.

Computing device 700 may include battery/power circuitry 708. Battery/power circuitry 708 may include one or more energy storage devices (e.g., batteries or capacitors) and/or circuitry for coupling components of computing device 700 to an energy source separate from computing device 700 (e.g., AC line power).

Computing device 700 may include a display device 703 (or corresponding interface circuitry, as discussed above). Display device 703 may include any visual indicators, such as a heads-up display, a computer monitor, a projector, a touchscreen display, a liquid crystal display (LCD), a light-emitting diode display, or a flat panel display, for example.

Computing device 700 may include an audio output device 704 (or corresponding interface circuitry, as discussed above). Audio output device 704 may include any device that generates an audible indicator, such as speakers, headsets, or earbuds, for example.

Computing device 700 may include an audio input device 710 (or corresponding interface circuitry, as discussed above). Audio input device 710 may include any device that generates a signal representative of a sound, such as microphones, microphone arrays, or digital instruments (e.g., instruments having a musical instrument digital interface (MIDI) output).

Computing device 700 may include a GPS device 709 (or corresponding interface circuitry, as discussed above). GPS device 709 may be in communication with a satellite-based system and may receive a location of computing device 700, as known in the art.

Computing device 700 may include other output device 705 (or corresponding interface circuitry, as discussed above). Examples of the other output device 705 may include an audio codec, a video codec, a printer, a wired or wireless transmitter for providing information to other devices, or an additional storage device.

Computing device 700 may include other input device 711 (or corresponding interface circuitry, as discussed above). Examples of the other input device 711 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 700 may include a security interface device 712. Security interface device 712 may include any device that provides security measures for computing device 700 such as intrusion detection, biometric validation, security encode or decode, access list management, malware detection, or spyware detection.

Computing device 700, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1A-7. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes an array of transistors in an IC die, wherein the transistors include substantially vertical channel regions, and an array of capacitor stacks, wherein the capacitor stacks include first electrodes coupled to pluralities of second electrodes, wherein the first electrodes are substantially vertically aligned with, and coupled to, corresponding channel regions in the array of transistors.

In one or more second embodiments, further to the first embodiments, the second electrodes are coupled to a corresponding first electrode by a ferroelectric material.

In one or more third embodiments, further to the first or second embodiments, an individual one of the transistors includes a gate dielectric, and the gate dielectric is around, and coaxial with, a corresponding one of the channel regions.

In one or more fourth embodiments, further to the first through third embodiments, a plurality of substantially parallel first conductive lines couples a first plurality of second electrodes in a first capacitor stack and a second plurality of second electrodes in a second capacitor stack.

In one or more fifth embodiments, further to the first through fourth embodiments, a second conductive line couples transistors in the array of transistors, and wherein the transistors include source or drain structures that couple the second conductive line and the channel regions.

In one or more sixth embodiments, further to the first through fifth embodiments, the array of transistors is a first array of first transistors, and further including a second array of second transistors, wherein the first electrodes are substantially coaxially aligned with, coupled to, and between corresponding first transistors and second transistors.

In one or more seventh embodiments, further to the first through sixth embodiments, an individual one of the second transistors includes a gate dielectric and a channel region, and the channel region is around, and coaxial with, the gate dielectric.

In one or more eighth embodiments, further to the first through seventh embodiments, the gate dielectric is in contact with the first electrode.

In one or more ninth embodiments, further to the first through eighth embodiments, a lower conductive line couples first transistors in the first array of transistors, and an upper conductive line couples second transistors in the second array of second transistors.

In one or more tenth embodiments, an apparatus includes a stack of capacitors in an IC die, the stack of capacitors including a first electrode and a plurality of second electrodes, wherein an individual one of the capacitors includes an individual one of the second electrodes, an individual portion of the first electrode, and a ferroelectric material therebetween, and wherein the first electrode includes a first vertical centerline, and a transistor in the IC die, the transistor over or under the first electrode, wherein the transistor includes a gate structure, and a channel structure extending vertically between source and drain structures, wherein the first electrode is coupled to an individual one of the source or drain structures, and wherein the channel structure includes a second vertical centerline substantially aligned with the first vertical centerline.

In one or more eleventh embodiments, further to the tenth embodiments, the gate structure surrounds the channel structure.

In one or more twelfth embodiments, further to the tenth or eleventh embodiments, the transistor is a first transistor, and further including a second transistor over or under, and coupled to, the first electrode, the second transistor including a third vertical centerline substantially aligned with the first and second vertical centerlines, and wherein the first electrode is between the first and second transistors.

In one or more thirteenth embodiments, further to the tenth through twelfth embodiments, the second transistor includes a second channel structure and a second gate structure, and the second channel structure surrounds the second gate structure.

In one or more fourteenth embodiments, further to the tenth through thirteenth embodiments, the stack of capacitors is a first stack of capacitors in an array of stacks of capacitors, the transistor is a first transistor in an array of transistors, and individual stacks of capacitors in the array of stacks of capacitors are coupled to corresponding transistors in the array of transistors.

In one or more fifteenth embodiments, a method includes forming a hole through a stack of alternating layers, the stack including layers of sacrificial material between isolation layers, depositing a gate dielectric and a channel material in the hole, forming a first electrode in the hole, wherein the first electrode is coaxial with the channel material or gate dielectric, exposing portions of the first electrode between the isolation layers by removing sacrificial material, depositing an insulator material over the first electrode, and forming a stack of capacitors by forming a plurality of second electrodes over the insulator material.

In one or more sixteenth embodiments, further to the fifteenth embodiments, depositing the insulator material over the first electrode includes depositing ferroelectric material over exposed portions of the first electrode.

In one or more seventeenth embodiments, further to the fifteenth or sixteenth embodiments, forming the hole exposes a conductive line below the stack.

In one or more eighteenth embodiments, further to the fifteenth through seventeenth embodiments, depositing the gate dielectric and the channel material includes depositing the gate dielectric over a sidewall of the hole and depositing the channel material over the gate dielectric and the conductive line.

In one or more nineteenth embodiments, further to the fifteenth through eighteenth embodiments, depositing the gate dielectric and the channel material includes depositing the channel material over a sidewall of the hole and depositing the gate dielectric over the channel material and the first electrode.

In one or more twentieth embodiments, further to the fifteenth through nineteenth embodiments, the first electrode is an individual one of a plurality of first electrodes, and further including forming an array of stacks of capacitors, wherein an individual stack of capacitors includes an individual one of the first electrodes.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
an array of transistors in an integrated circuit (IC) die, wherein the transistors comprise substantially vertical channel regions; and
an array of capacitor stacks, wherein the capacitor stacks comprise first electrodes coupled to pluralities of second electrodes, wherein the first electrodes are substantially vertically aligned with, and coupled to, corresponding channel regions in the array of transistors.

2. The apparatus of claim 1, wherein the second electrodes are coupled to a corresponding first electrode by a ferroelectric material.

3. The apparatus of claim 1, wherein an individual one of the transistors comprises a gate dielectric, and the gate dielectric is around, and coaxial with, a corresponding one of the channel regions.

4. The apparatus of claim 1, wherein a plurality of substantially parallel first conductive lines couples a first plurality of second electrodes in a first capacitor stack and a second plurality of second electrodes in a second capacitor stack.

5. The apparatus of claim 1, wherein a second conductive line couples transistors in the array of transistors, and wherein the transistors comprise source or drain structures that couple the second conductive line and the channel regions.

6. The apparatus of claim 1, wherein the array of transistors is a first array of first transistors, and further comprising a second array of second transistors, wherein the first electrodes are substantially coaxially aligned with, coupled to, and between corresponding first transistors and second transistors.

7. The apparatus of claim 6, wherein an individual one of the second transistors comprises a gate dielectric and a channel region, and the channel region is around, and coaxial with, the gate dielectric.

8. The apparatus of claim 7, wherein the gate dielectric is in contact with the first electrode.

9. The apparatus of claim 6, wherein a lower conductive line couples first transistors in the first array of first transistors, and an upper conductive line couples second transistors in the second array of second transistors.

10. An apparatus, comprising:
a stack of capacitors in an integrated circuit (IC) die, the stack of capacitors comprising a first electrode and a plurality of second electrodes, wherein an individual one of the capacitors comprises an individual one of the second electrodes, an individual portion of the first electrode, and a ferroelectric material therebetween, and wherein the first electrode comprises a first vertical centerline; and
a transistor in the IC die, the transistor over or under the first electrode, wherein the transistor comprises a gate structure, and a channel structure extending vertically between source and drain structures, wherein the first electrode is coupled to a one of the source or drain structures, and wherein the channel structure comprises a second vertical centerline substantially aligned with the first vertical centerline.

11. The apparatus of claim 10, wherein the gate structure surrounds the channel structure.

12. The apparatus of claim 10, wherein the transistor is a first transistor, and further comprising a second transistor over or under, and coupled to, the first electrode, the second transistor comprising a third vertical centerline substantially aligned with the first and second vertical centerlines, and wherein the first electrode is between the first and second transistors.

13. The apparatus of claim 12, wherein the second transistor comprises a second channel structure and a second gate structure, and the second channel structure surrounds the second gate structure.

14. The apparatus of claim 10, wherein the stack of capacitors is a first stack of capacitors in an array of stacks of capacitors, the transistor is a first transistor in an array of transistors, and individual stacks of capacitors in the array of stacks of capacitors are coupled to corresponding transistors in the array of transistors.

15. A method, comprising:
forming a hole through a stack of alternating layers, the stack comprising layers of sacrificial material between isolation layers;
depositing a gate dielectric and a channel material in the hole;
forming a first electrode in the hole, wherein the first electrode is coaxial with the channel material or gate dielectric;
exposing portions of the first electrode between the isolation layers by removing sacrificial material;
depositing an insulator material over the first electrode; and
forming a stack of capacitors by forming a plurality of second electrodes over the insulator material.

16. The method of claim 15, wherein depositing the insulator material over the first electrode comprises depositing ferroelectric material over exposed portions of the first electrode.

17. The method of claim 15, wherein forming the hole exposes a conductive line below the stack.

18. The method of claim 17, wherein depositing the gate dielectric and the channel material comprises depositing the gate dielectric over a sidewall of the hole and depositing the channel material over the gate dielectric and the conductive line.

19. The method of claim 15, wherein depositing the gate dielectric and the channel material comprises depositing the channel material over a sidewall of the hole and depositing the gate dielectric over the channel material and the first electrode.

20. The method of claim 15, wherein the first electrode is an individual one of a plurality of first electrodes, and further comprising forming an array of stacks of capacitors, wherein an individual stack of capacitors comprises an individual one of the first electrodes.
